(19) United States
(12) Patent Application Publication
(10) Pub. No.: US 2026/0231799 A1
(43) Pub. Date: Aug. 6, 2026

(54) CIRCUIT BOARD, AND SEMICONDUCTOR PACKAGE COMPRISING SAME

(71) Applicant: LG INNOTEK CO., LTD., Seoul (KR)

(72) Inventors: Young Jae CHO, Seoul (KR); Jin Mi NOH, Seoul (KR); Jong Bae SHIN, Seoul (KR)

(73) Assignee: LG INNOTEK CO., LTD., Seoul (KR)

(21) Appl. No.: 19/152,555

(22) PCT Filed: Feb. 1, 2024
(86) PCT No.: PCT/KR2024/001550

§ 371 Date: Jul. 31, 2025

(30) Foreign Application Priority Data
Feb. 1, 2023 (KR) 10-2023-0013780

(51) Int. Cl. H10W 70/685

(52) U.S. Cl. CPC H10W 70/685

(57) ABSTRACT

A circuit board according to an embodiment includes a first insulating layer; a metal layer disposed on the first insulating layer; and a second insulating layer disposed on the metal layer and including a cavity, and wherein the metal layer includes a plurality of metal patterns disposed and spaced apart from each other along a circumferential direction of a lower end of a side wall of the cavity.

### TECHNICAL FIELD

An embodiment relates to a circuit board and a semiconductor package including the same.

### BACKGROUND ART

As the performance of electric/electronic products progresses, technologies for attaching a larger number of packages to a limited-sized substrate are being proposed and studied.

A typical semiconductor package has a structure in which a plurality of chips are mounted. In addition, a size of the semiconductor package is increasing due to high specifications of products to which the semiconductor package is applied and the adoption of multiple chips such as HBM (High Bandwidth Memory). Accordingly, the semiconductor package includes an interposer to connect a plurality of chips.

In addition, semiconductor packages applied to products that provide the Internet of Things (IoT), autonomous vehicles, and high-performance servers require high performance and high reliability in accordance with the trend of high integration.

Furthermore, the semiconductor package has a vertical connection structure between a plurality of substrates, interposers, and semiconductor devices. Accordingly, a thickness of the semiconductor package in the vertical direction can increase depending on the thickness and number of the substrate, interposer, and semiconductor devices.

Therefore, the semiconductor package is reducing the thickness in the vertical direction by using a substrate with a cavity.

At this time, a de-smear process must be performed in a process of manufacturing a substrate including the cavity. That is, if the de-smear process is not performed, the adhesion between a molding member disposed in the cavity and the substrate decreases, and thus the molding member is separated from the substrate.

In addition, when the de-smear process is performed, a bottom surface of the cavity may be etched together with a side wall of the cavity. As a result, damage may occur to the bottom surface of the cavity, which may cause problems with the physical reliability of the substrate.

In addition, the bottom surface of the cavity may be an upper surface of a thermosetting resin including glass fibers. Therefore, as the de-smear process is performed, the thermosetting resin is etched, and thus the glass fibers provided in the thermosetting resin may be exposed through the cavity. In addition, the exposed glass fibers may act as a factor causing defects such as copper migration.
(Patent Document 1) KR 10-2012-0045639 A

### DISCLOSURE

### Technical Problem

The embodiment provides a circuit board having a novel structure and a semiconductor package including the same.

In addition, the embodiment provides a circuit board including a cavity and a semiconductor package including the same.

In addition, the embodiment provides a circuit board having an improved circuit integration and a semiconductor package including the same.

In addition, the embodiment provides a circuit board having improved electrical reliability and/or mechanical reliability and a semiconductor package including the same.

In addition, the embodiment provides a circuit board having improved warpage characteristics and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a first insulating layer; a metal layer disposed on the first insulating layer; and a second insulating layer disposed on the metal layer and having a cavity, wherein the metal layer includes a plurality of metal patterns disposed spaced apart from each other along a circumferential direction of a lower end of a side wall of the cavity.

In addition, the circuit board further comprises a first circuit pattern layer disposed on the first insulating layer, wherein the first circuit pattern layer includes a first pad that overlaps the cavity in a vertical direction; and a second pad that does not overlap the cavity in a vertical direction.

In addition, the first circuit pattern layer further includes a connection pattern that connects between the first pad and the second pad, wherein the connection pattern includes a first portion vertically overlapping the cavity and not covered by the second insulating layer, and a second portion not vertically overlapping the cavity and covered by the second insulating layer.

In addition, the connection pattern is provided to cross between the plurality of metal patterns on the first insulating layer.

In addition, the connection pattern is not connected to each of the plurality of metal patterns.

In addition, the connection pattern is provided with a plurality of connection patterns, and at least one of the plurality of connection patterns is connected to at least one of the plurality of metal patterns.

In addition, the plurality of metal patterns have different widths in the horizontal direction along the circumferential direction.

In addition, the plurality of metal patterns are spaced apart with a spacing in a range of 2 μm to 12 μm along the circumferential direction.

In addition, each of the first pad and the second pad includes a first layer disposed on the first insulating layer; and a second layer disposed on the first layer, and wherein a thickness of each of the plurality of metal patterns corresponds to a thickness of the second layer of the first and second pads.

In addition, the second insulating layer includes a first recess portion concavely provided in a horizontal direction from a lower end of a side wall of the cavity toward an outer surface of the second insulating layer.

In addition, the first recess portion includes a plurality of first recesses provided between the plurality of metal patterns and the side wall of the cavity, and a portion of the side surface of each of the plurality of metal patterns is exposed through the first recess and the cavity.

In addition, a vertical distance of each of the plurality of first recesses in the vertical direction corresponds to a thickness of each of the plurality of metal patterns.

In addition, the first insulating layer includes a second recess portion connected to a lower end of the side wall of the cavity and concavely provided in the vertical direction from an upper surface of the first insulating layer toward a lower surface of the first insulating layer.

In addition, the second recess portion includes a plurality of second recesses spaced apart from each other along the circumferential direction, and the plurality of first recesses and the plurality of second recesses are alternately disposed along the circumferential direction.

Meanwhile, a semiconductor package according to an embodiment comprises a first insulating layer; a second insulating layer disposed on the first insulating layer and including a cavity; a first circuit pattern layer including a first pad disposed between the first insulating layer and the second insulating layer and overlapping the cavity in a vertical direction, a second pad not overlapping the cavity in the vertical direction, and a connection pattern connecting the first pad and the second pad; a bonding member disposed on the first pad; a connection member disposed on the bonding member; and a metal layer provided on the first insulating layer along a circumferential direction of a lower end of a side wall of the cavity, wherein the metal layer includes a plurality of metal patterns spaced apart from each other along the circumferential direction.

In addition, the semiconductor package includes a molding member disposed in the cavity to mold the connection member, and the molding member is in contact with the plurality of metal patterns.

In addition, the second insulating layer includes a first recess portion concavely provided in a horizontal direction from a lower end of a side wall of the cavity toward an outer surface of the second insulating layer, and the first recess portion includes a plurality of first recesses provided between the plurality of metal patterns and the side wall of the cavity, and the molding member is provided to fill the plurality of first recesses.

In addition, the first insulating layer includes a plurality of second recesses concavely provided in a vertical direction from an upper surface of the first insulating layer toward a lower surface of the first insulating layer and alternately provided with the plurality of first recesses along the circumferential direction, and the molding member is provided to further fill the plurality of second recesses.

In addition, the connecting member includes at least one of an interposer, a semiconductor device, an organic bridge, and an inorganic bridge.

### Advantageous Effects

The embodiment may include a first insulating layer and a second insulating layer disposed on the first insulating layer and including a cavity. A metal layer is disposed along a circumferential direction of a lower end of a side wall of the cavity and is provided between the first insulating layer and the second insulating layer. The metal layer includes a plurality of metal patterns spaced apart from each other along the circumferential direction.

The plurality of metal patterns may function as a reinforcing member that improves a rigidity of the circuit board. For example, the plurality of metal patterns may disperse or alleviate stress acting on the circuit board, thereby improving warpage characteristics of the circuit board. In addition, the plurality of metal patterns may alleviate horizontal direction expansion of the circuit board due to thermal stress occurring in a manufacturing environment or a usage environment of the circuit board, thereby improving mechanical reliability and/or physical reliability of the circuit board and a semiconductor package including the circuit board.

In addition, the embodiment further includes a connection pattern disposed on the first insulating layer and directly connecting the first pad and the second pad. The connection pattern may be provided to cross between the plurality of metal patterns. At this time, a plurality of connection patterns may be provided. At this time, the plurality of metal patterns are provided spaced apart from each other along the circumferential direction, and accordingly, the plurality of connection patterns may not be electrically connected to each other on the first insulating layer. Therefore, the embodiment can directly connect the first pad and the second pad using the connection pattern, and accordingly, a first through electrode overlapping the first pad in the vertical direction can be omitted. Furthermore, the embodiment can reduce a length of a signal line therebetween by directly connecting the first pad and the second pad using the connection pattern. For example, a signal line including the connection pattern can be shorter than a signal line including the first through electrode. Therefore, the embodiment can minimize signal transmission loss by reducing the signal transmission line between the first pad and the second pad, and thereby improve electrical characteristics. Furthermore, the embodiment can improve the circuit integration by arranging the connection pattern that directly connects the first pad and the second pad.

Meanwhile, the second insulating layer of the embodiment may include a first recess portion provided between the plurality of metal patterns and the lower end of the side wall of the cavity. The first recess portion may disperse or alleviate stress acting on the first insulating layer and the second insulating layer, thereby improving the warpage characteristics of the circuit board. For example, the first recess portion may reduce an area of the interface between the first insulating layer and the second insulating layer, thereby dispersing stress acting on the second insulating layer. Accordingly, the first recess portion may alleviate a phenomenon in which the circuit board is bent in a specific direction (for example, a phenomenon in which both ends of the circuit board are bent upward or a phenomenon in which both ends of the circuit board are bent downward).

In addition, the first insulating layer of the embodiment may include a second recess portion provided along the circumferential direction. The second recess portion may be provided concavely in a vertical direction from the upper surface to the lower surface of the first insulating layer. At this time, the first recess portion is a recess provided in the second insulating layer along the horizontal direction, and the second recess portion is a recess provided in the first insulating layer along the vertical direction. Therefore, the embodiment can disperse or alleviate stress applied to the circuit board by using the first and second recess portions, thereby improving warpage characteristics of the circuit board.

For example, the first and second recess portions can alleviate expansion of the circuit board in the horizontal direction due to thermal stress occurring in the manufacturing environment or the usage environment of the circuit board, thereby improving the mechanical reliability and/or physical reliability of the circuit board and the semiconductor package including the circuit board. At this time, the second insulating layer can include an insulating material different from that of the first insulating layer. Accordingly, the first insulating layer and the second insulating layer can have different coefficients of thermal expansion, and thus warpage of the circuit board in the vertical direction can occur. Accordingly, the first and second recess portions can prevent the circuit board from being bent in a specific direction (for example, the phenomenon in which both ends of the circuit board are bent upward or the phenomenon in which both ends of the circuit board are bent downward).

Therefore, the embodiment can minimize the degree of warpage along the vertical direction of the circuit board and the semiconductor package or the degree of expansion or contraction along the horizontal direction, thereby improving the mechanical and/or physical reliability of the circuit board and the semiconductor package. Furthermore, the embodiment can enable the semiconductor device disposed on the circuit board to operate stably, thereby improving operating characteristics of the electronic product and/or server to which the semiconductor package is applied.

Meanwhile, the plurality of metal patterns of the embodiment can have different widths in the horizontal direction along the circumferential direction. For example, a width of the metal pattern in the horizontal direction in a region with a relatively low metal density can be larger than a width of the metal pattern in the horizontal direction in a region with a relatively high metal density. Accordingly, the embodiment can minimize the warpage of the circuit board caused by a difference in the metal density, thereby further improving the physical reliability and/or electrical reliability of the circuit board and the semiconductor package.

In addition, the embodiment can perform a de-smear process of the second insulating layer after the cavity is formed in a state in which a barrier layer is provided, and based on this, can prevent the glass fiber of the first insulating layer from being exposed, and further solve the physical reliability and/or electrical reliability problem caused thereby. Furthermore, the embodiment can determine the de-smear process conditions under conditions that do not consider the exposure of the glass fiber. For example, the embodiment can determine the de-smear conditions under conditions that can optimally improve the adhesion between the second insulating layer and the second circuit pattern layer, thereby improving the adhesion between the second insulating layer and the second circuit pattern layer without causing the problem of the reinforcing member being exposed.

Meanwhile, the de-smear process of the embodiment can be performed under a state in which a through hole and a cavity penetrating the second insulating layer are formed. Therefore, in the de-smear process, an inner wall of the through hole and an inner wall of the cavity can be surface-treated together. Through this, the adhesion between the second through electrode disposed in the through hole and the second insulating layer can be improved. Furthermore, the embodiment can improve the adhesion between the molding member disposed in the cavity and the second insulating layer.

Furthermore, the molding member can be provided to fill at least one of the first recess portion and the second recess portion. Therefore, the embodiment can further improve the bonding strength between the molding member and the circuit board.

### DESCRIPTION OF DRAWINGS

FIG. 1 is a cross-sectional view showing a circuit board according to a first embodiment.

FIG. 2 and FIG. 3 are plan views for explaining a process of providing a metal pattern on the circuit board of FIG. 1.

FIG. 4 is a plan view showing a metal pattern provided on the circuit board of FIG. 1.

FIG. 5 is a cross-sectional view of the circuit board cut along a direction A-A′ of FIG. 4.

FIG. 6 is a cross-sectional view showing a circuit board according to a second embodiment.

FIG. 7 is a cross-sectional view showing a circuit board according to a third embodiment.

FIG. 8 is a cross-sectional view showing a circuit board according to a fourth embodiment.

FIG. 9 is a plan view showing the circuit board of FIG. 8.

FIG. 10 is a cross-sectional view showing a circuit board according to a fifth embodiment.

FIG. 11 is a plan view of the circuit board of FIG. 10.

FIG. 12 is an enlarged view showing a partial region of the circuit board of FIG. 10.

FIG. 13 is a drawing showing an upper surface of a first region of a first insulating layer according to an embodiment and a comparative example.

FIG. 14 is a cross-sectional view showing a semiconductor package according to an embodiment.

FIGS. 15 to 28 are drawings showing a manufacturing method of the circuit board of FIG. 8 according to the embodiment in order of processes.

### BEST MODE

Hereinafter, embodiments will be described in detail with reference to the accompanying drawings.

However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art. Further, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present invention, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements. Furthermore, when expressed as “on (over)” or “under (below)”, it may include not only the upper direction but also the lower direction based on one element.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a circuit board according to an embodiment and a semiconductor package including the same will be described. The semiconductor package may have various vertical and horizontal stacked structures including the circuit board described below. For example, the semiconductor package may include a connection member including at least one semiconductor device coupled to the circuit board and/or at least one of a bridge substrate of high-density wiring and an interposer.

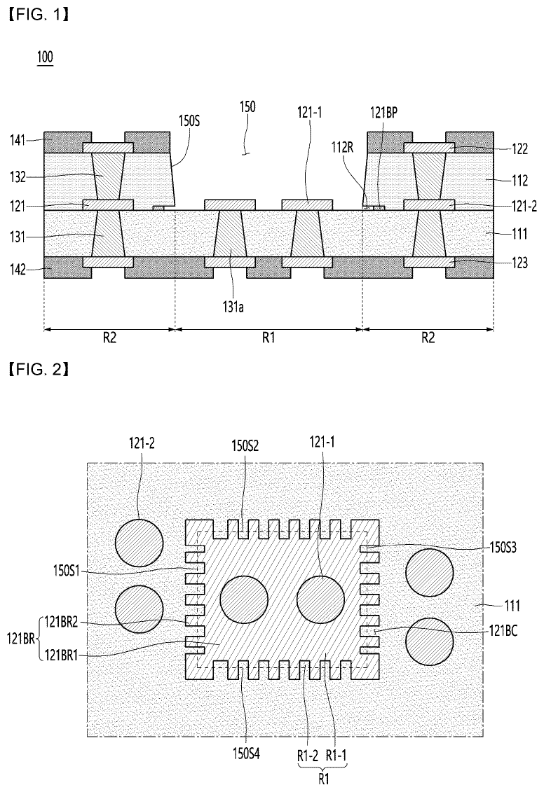

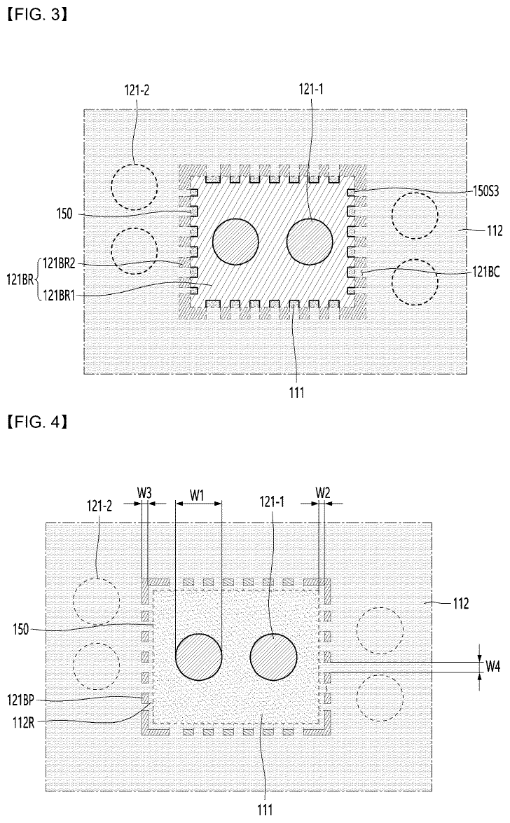

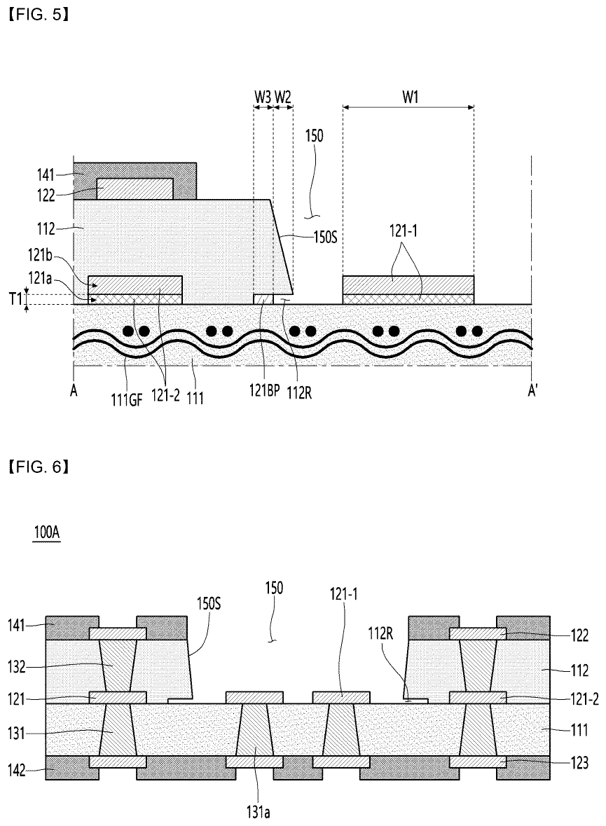

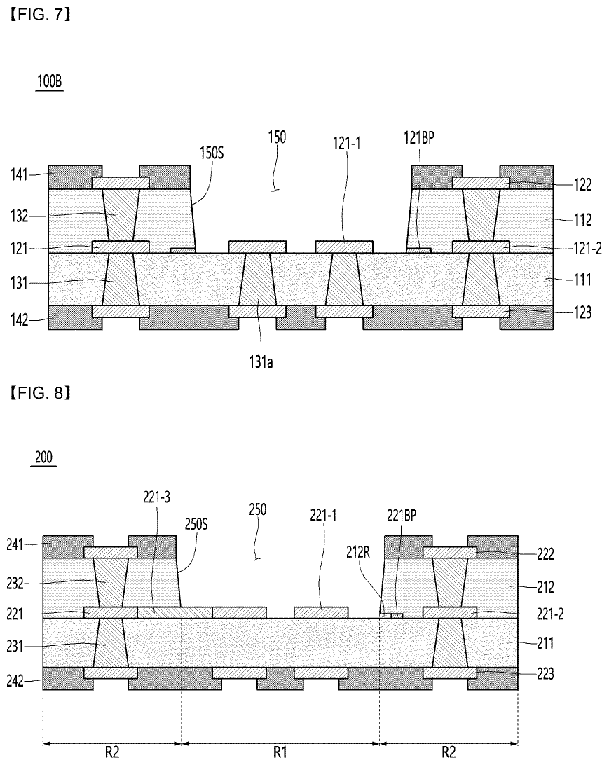

FIG. 1 is a cross-sectional view showing a circuit board according to a first embodiment, FIG. 2 and FIG. 3 are plan views for explaining a process of providing a metal pattern on the circuit board of FIG. 1, FIG. 4 is a plan view showing a metal pattern provided on the circuit board of FIG. 1, and FIG. 5 is a cross-sectional view of the circuit board cut along a direction A-A′ of FIG. 4.

First, referring to FIG. 1, a schematic structure of a circuit board according to the first embodiment will be described.

Referring to FIG. 1, the circuit board of the embodiment may include a plurality of insulating layers. Each of the plurality of insulating layers may have a single-layer structure, or alternatively, may be composed of a plurality of layers.

Specifically, the circuit board may include a first insulating layer 111 and a second insulating layer 112. At this time, the first insulating layer 111 may have a single-layer structure as shown in FIG. 1, or alternatively, may have a multiple-layer structure.

The second insulating layer 112 may be disposed on the first insulating layer 111. The second insulating layer 112 may have a single-layer structure, or alternatively, may have a multiple-layer structure.

The second insulating layer 112 may include a cavity 150. At this time, when the second insulating layer 112 has a multi-layer structure, the cavity 150 can penetrate one of the multi-layer second insulating layers, or alternatively, can penetrate at least two layers simultaneously.

In one embodiment, the first insulating layer 111 and the second insulating layer 112 may include a same insulating material. In this case, the first insulating layer 111 may mean an insulating layer that does not have a cavity 150, and the second insulating layer 112 may mean an insulating layer that has a cavity 150.

In another embodiment, the first insulating layer 111 and the second insulating layer 112 may include different insulating materials.

However, for the convenience of explanation, the first insulating layer 111 and the second insulating layer 112 are described as having a single-layer structure and including different insulating materials.

The first insulating layer 111 and the second insulating layer 112 may include different insulating materials. For example, the first insulating layer 111 may include a thermosetting resin. The second insulating layer 112 may include a photocurable resin. However, the embodiment is not limited thereto, and each of the first insulating layer 111 and the second insulating layer 112 may be provided with a thermosetting resin, or each of the first insulating layer 111 and the second insulating layer 112 may be provided with a photocurable resin, or the first insulating layer 111 may be provided with a photocurable resin and the second insulating layer 112 may be provided with a thermosetting resin.

The second insulating layer 112 may include a cavity 150. The cavity 150 may penetrate upper and lower surfaces of the second insulating layer 112. The cavity 150 may include a bottom surface and a side wall 150S.

The bottom surface of the cavity 150 may mean the upper surface of the first insulating layer 111 that is vertically overlapped with the cavity 150. In addition, the side wall 150S of the cavity 150 may mean the side wall of the second insulating layer 112 that is overlapped with the cavity 150 in a vertical direction.

The side wall 150S of the cavity 150 may have a slope. For example, the side wall 150S of the cavity 150 may have a slope in which a width of the cavity 150 decreases from the upper surface toward the lower surface of the second insulating layer 112. However, the embodiment is not limited thereto. For example, the side wall 150S may have a slope in which the width of the cavity 150 decreases from the lower surface of the second insulating layer 112 to the upper surface of the second insulating layer 112. Furthermore, although the drawing illustrates that the side wall 150S has one slope, it is not limited thereto. For example, the side wall 150S may include at least one inflection portion, and may be inclined with different slopes at the inflection portion.

The upper surface of the first insulating layer 111 may be divided into a plurality of regions. For example, the first insulating layer 111 may include a first region R1 that vertically overlaps the cavity 150. At this time, when the cavity 150 has different widths in a thickness direction of the second insulating layer 112, the first region R1 may mean a region that vertically overlaps with a lower region of the cavity 150 corresponding to a lower end of the side wall 150S.

In addition, the first insulating layer 111 may include a second region R2 that does not vertically overlap with the cavity 150. The second region R2 may mean a region of an upper surface of the first insulating layer 111 that is covered with the second insulating layer 112.

At this time, the circuit board of the embodiment may have a reinforcing portion. The reinforcing member may disperse stress acting according to expansion and/or contraction due to thermal stress of the circuit board, and may prevent bending of the circuit board in the vertical direction and/or the horizontal direction. The reinforcing portion of the first embodiment may include a first recess portion 112R and a metal layer 121BP described below. For example, the reinforcing portion of the first embodiment may include a plurality of reinforcing patterns, and the plurality of reinforcing patterns may include a plurality of first recesses of the first recess portion 112R and a plurality of metal patterns of the metal layer 121BP, respectively.

For example, the second insulating layer 112 may have a first recess portion 112R that is a part of the reinforcing portion.

The first recess portion 112R may be connected to a lower end of a side wall 150S of the second insulating layer 112. For example, the lower end of the side wall 150S of the second insulating layer 112 may include a portion connected to the first recess portion 112R. At this time, the lower end of the side wall 150S of the second insulating layer 112 may be partially connected to the first recess portion 112R. For example, the lower end of the side wall of the second insulating layer 112 may include a connection portion connected to the first recess portion 112R and a non-connection portion not connected to the first recess portion 112R.

Therefore, the lower end of the side wall 150S of the second insulating layer 112 may have a step along a circumferential direction. For example, the lower end of the side wall 150S of the second insulating layer 112 may include a connection portion and a non-connection portion with the first recess portion 112R, and the connection portion and the non-connection portion may have different heights. The connection portion of the lower end of the side wall 150S of the second insulating layer 112 may be positioned higher than the non-connection portion. For example, the connection portion of the lower end of the side wall 150S of the second insulating layer 112 may not be in contact with the upper surface of the first insulating layer 111, and the non-connection portion may be in contact with the upper surface of the first insulating layer 111.

At this time, the first recess portion 112R may be provided along the horizontal direction in the second insulating layer 112. For example, the first recess portion 112R may be provided concavely from the lower end of the side wall 150S of the cavity 150 toward an outer surface of the second insulating layer 112.

That is, the first recess portion 112R may be provided concavely in a horizontal direction away from the cavity 150 at the lower end of the side wall 150S of the cavity 150 of the second insulating layer 112. The first recess portion 112R may overlap the second region R2 of the first insulating layer 111 located adjacent to the first region R1 of the first insulating layer 111 in the vertical direction. The first recess portion 112R may be a region in which a portion of a barrier layer 121BR protecting the upper surface of the first region R1 of the first insulating layer 111 is removed.

The first region R1 of the first insulating layer 111 may overlap vertically with the cavity 150 and may not contact the second insulating layer 112. In addition, a portion of the second region R2 of the first insulating layer 111 may overlap vertically with the first recess portion 112R and may not contact the second insulating layer 112.

The embodiment may provide a first recess portion 112R that is concave in the horizontal direction in the second insulating layer 112 adjacent to the cavity 150. Through this, the embodiment can disperse or alleviate the stress acting on the first insulating layer 111 and the second insulating layer 112, thereby improving warpage characteristics of the circuit board.

For example, the first recess portion 112R can reduce an area of an interface between the first insulating layer 111 and the second insulating layer 112, thereby dispersing the stress acting on the second insulating layer 112. Therefore, the first recess portion 112R can alleviate the phenomenon of the circuit board being bent in a specific direction (for example, a phenomenon of both ends of the circuit board being bent upward or a phenomenon of both ends of the circuit board being bent downward).

At this time, the first recess portion 112R is provided along a circumferential direction of the lower end of the side wall 150S of the cavity 150. Preferably, the first recess portion 112R may include a plurality of first recesses provided along the circumferential direction of the lower end of the side wall 150S of the cavity 150.

In addition, the plurality of first recesses of the first recess portion 112R are provided spaced apart from each other along the circumferential direction of the lower end of the side wall 150S of the cavity 150. Accordingly, the embodiment can efficiently distribute stress applied to the second insulating layer 112 while maintaining the adhesion between the first insulating layer 111 and the second insulating layer 112.

For example, in contrast to a structure of the present invention, the first recess portion 112R may be provided in a closed loop shape that is connected to each other along the circumferential direction of the lower end of the side wall 150S of the cavity 150. In this case, the adhesion between the first insulating layer 111 and the second insulating layer 112 may be reduced, and thus, the second insulating layer 112 may have a problem of being peeled off from the first insulating layer 111. In addition, when the first recess portion 112R has a closed loop shape, stress distribution in the horizontal direction due to contraction and/or expansion of the second insulating layer 112 is possible, but the degree of warpage in the vertical direction may increase. Therefore, the embodiment allows the first recess portion 112R to have a plurality of first recesses spaced apart from each other along the circumferential direction, thereby achieving the effects of improving the adhesion between the first insulating layer 111 and the second insulating layer 112 and improving the warpage in the vertical direction along with stress distribution.

In addition, each of the plurality of first recesses of the first recess portion 112R may have a same width in the horizontal direction along the circumferential direction of the lower end of the side wall 150S of the cavity 150, but is not limited thereto. For example, each of the plurality of first recesses may have different widths in the horizontal direction along the circumferential direction of the lower end of the side wall 150S of the cavity 150. In addition, the width of each of the plurality of first recesses in the horizontal direction may be determined according to a warpage direction of the circuit board, but is not limited thereto.

Therefore, the embodiment can minimize the degree of expansion or contraction of the circuit board and the semiconductor package along the horizontal direction, thereby improving the mechanical and/or physical reliability of the circuit board and the semiconductor package. Furthermore, the embodiment can enable the semiconductor device disposed on the circuit board to operate stably, thereby improving the operating characteristics of the electronic product and/or server to which the semiconductor package is applied.

In addition, the first recess portion 112R may be filled with a molding member in the semiconductor package. The first recess portion 112R may function as an anchor for improving a bonding strength between the molding member and the circuit board. Therefore, the embodiment may solve the mechanical reliability problem of the molding member being peeled off from the circuit board.

Meanwhile, a circuit pattern layer is disposed on the first insulating layer 111 and the second insulating layer 112. At this time, a part of the circuit pattern layer may not function as a circuit (for example, a function of transmitting an electrical signal), and this may be defined as a ‘metal layer’. Therefore, the circuit pattern layer may mean a layer that functions as a circuit, and the metal layer may mean a layer that does not function as a circuit, but is not limited thereto. For example, at least one of the plurality of metal patterns of the metal layer may be connected to the circuit pattern layer, and the metal pattern connected to the circuit pattern layer may function to transmit an electrical signal together with the circuit pattern layer. At this time, the ‘metal layer’ may be a part of the barrier layer and may form a reinforcing portion together with the first recess portion 112R. This will be described in detail below.

The first circuit pattern layer 121 may be provided between the upper surface of the first insulating layer 111 and the lower surface of the second insulating layer 112.

The second circuit pattern layer 122 may be provided on the upper surface of the second insulating layer 112.

The third circuit pattern layer 123 may be provided on the lower surface of the first insulating layer 111.

That is, the first circuit pattern layer 121 may be disposed on the first insulating layer 111. For example, the first circuit pattern layer 121 may protrude on the upper surface of the first insulating layer 111.

The second circuit pattern layer 122 may protrude on the upper surface of the second insulating layer 112. The second circuit pattern layer 122 may refer to an uppermost circuit pattern layer disposed on an uppermost side of the circuit board.

The third circuit pattern layer 123 may protrude below the lower surface of the first insulating layer 111. The third circuit pattern layer 123 may refer to a lowermost circuit pattern layer disposed at a lowermost side of the circuit board.

Each of the first circuit pattern layer 121, the second circuit pattern layer 122, and the third circuit pattern layer 123 may include a pad and a trace (or a connection pattern) according to a function. The pad may be a mounting pad on which a device or chip is mounted, or a terminal pad connected to an external substrate. The trace may be a long signal wiring line connecting a plurality of pads. The trace is a fine pattern having a width smaller than the pad. For example, a spacing between the plurality of traces in the embodiment may be in a range of 2 μm to 15 μm, and a line width of each trace may be in a range of 2 μm to 15 μm.

The circuit pattern layers as described above may be formed of at least one metal material selected from gold (Au), silver (Ag), platinum (Pt), titanium (Ti), tin (Sn), copper (Cu), and zinc (Zn). In addition, the circuit pattern layers may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first circuit pattern layer 121, the second circuit pattern layer 122, and the third circuit pattern layer 123 may be formed of copper (Cu) having high electrical conductivity and a relatively low price.

The first circuit pattern layer 121, the second circuit pattern layer 122, and the third circuit pattern layer 123 may each have a thickness in a range of 10 μm to 25 μm. For example, the first circuit pattern layer 121, the second circuit pattern layer 122, and the third circuit pattern layer 123 may each have a thickness in a range of 10 μm to 23 μm. The first circuit pattern layer 121, the second circuit pattern layer 122, and the third circuit pattern layer 123 may each have a thickness in a range of 10 μm to 20 μm.

If the thickness of each of the first circuit pattern layer 121, the second circuit pattern layer 122, and the third circuit pattern layer 123 is less than 10 μm, the resistance of the circuit pattern may increase, and thus the signal transmission efficiency may decrease. For example, if the thickness of each of the first circuit pattern layer 121, the second circuit pattern layer 122, and the third circuit pattern layer 123 is less than 10 μm, the signal transmission loss may increase. For example, if the thickness of each of the first circuit pattern layer 121, the second circuit pattern layer 122, and the third circuit pattern layer 123 exceeds 25 μm, the line width of the circuit patterns may increase, and thus the overall volume of the circuit board may increase.

The first circuit pattern layer 121 may include a plurality of pads.

The first circuit pattern layer 121 may include a first pad 121-1 disposed on the first region R1 of the first insulating layer 111. The first pad 121-1 may vertically overlap with the cavity 150. Therefore, the first pad 121-1 may not contact the second insulating layer 112.

The first circuit pattern layer 121 may include a second pad 121-2 disposed on the second region R2 of the first insulating layer 111. The second pad 121-2 may not vertically overlap with the cavity 150. Therefore, the second pad 121-2 may be covered with the second insulating layer 112.

At this time, at least a part of the upper surface of the first region R1 of the first insulating layer 111 may vertically overlap with the first pad 121-1, and the remaining part may not vertically overlap with the first circuit pattern layer 121 and the second insulating layer 112.

Accordingly, when a de-smear process is performed after the formation of the cavity 150, a part of the first region R1 of the first insulating layer 111 where the first pad 121-1 is not disposed may also be etched together. In addition, when the first region R1 of the first insulating layer 111 is etched in the de-smear process, glass fibers included in the first insulating layer 111 may be exposed through the cavity 150. The exposed glass fibers may cause reliability problems such as copper migration.

Therefore, the circuit board of the embodiment can form a cavity 150 in a state where a barrier layer 121BR is disposed on the first region R1 of the first insulating layer 111. The barrier layer 121BR can form a reinforcing portion including a first recess portion 112R and a metal layer 121BP to improve mechanical reliability and/or electrical reliability of the circuit board, while protecting the upper surface of the first region R1 of the first insulating layer 111 in the de-smear process.

In addition, in a manufacturing process of the circuit board of the first embodiment, the barrier layer 121BR can be partially removed. Therefore, the reinforcing portion of the circuit board of the first embodiment can include a metal layer 121BP corresponding to a part of the barrier layer 121BR and connected to the first recess portion 112R.

The metal layer 121BP may be provided along the circumferential direction of the lower end of the side wall 150S of the cavity 150. Preferably, the metal layer 121BP may be provided with a plurality of metal patterns, and each of the plurality of metal patterns may correspond to each of the plurality of first recesses of the first recess portion 112R. That is, a part of the barrier layer 121BR may be removed to form the first recess portion 112R of the reinforcing portion, and a remaining part of the barrier layer 121BR may not be removed to form the metal layer 121BP of the reinforcing portion. At this time, the metal layer 121BP may be disposed on a same layer as the first circuit pattern layer 221 and may not be electrically connected to the first circuit pattern layer 221. Therefore, the metal layer 121BP may be referred to as a dummy pattern or barrier pattern that is not electrically connected to the first circuit pattern layer 221.

The embodiment may allow a first recess portion 112R to have a plurality of first recesses spaced apart from each other along the circumferential direction of the lower end of the side wall 150S of the cavity 150, and may allow a metal layer 121BP to have a plurality of metal patterns corresponding to each of the plurality of first recesses of the first recess portion 112R.

To summarize, the second insulating layer 112 may have the first recess portion 112R provided along the circumferential direction of the lower end of the side wall 150S of the cavity 150, and the metal layer 121BP may be provided along the circumferential direction of the first recess portion 112R. In addition, the first recess portion 112R and the metal layer 121BP may be connected to each other in a horizontal direction and may form a reinforcing portion.

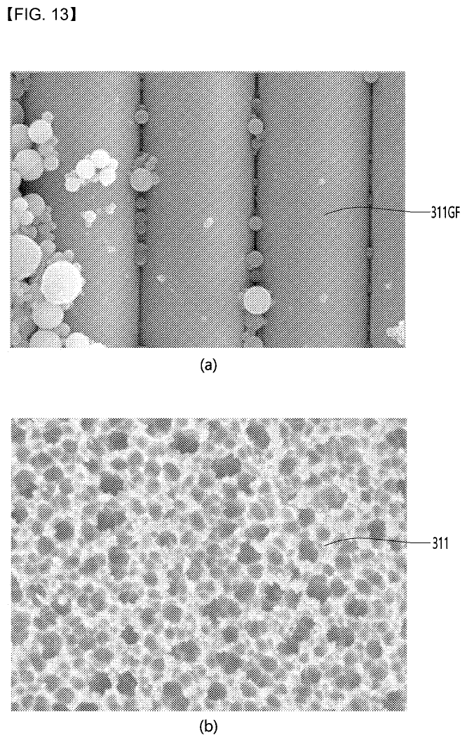

For example, each of the metal layers 121BP has a plurality of metal patterns spaced apart from each other along the circumferential direction, and accordingly, it may be possible to arrange a connection pattern 221-3 that directly connects a plurality of pads, as in FIG. 8. That is, the metal layer 121BP of the embodiment enables the arrangement of the connection pattern 221-3 while preventing the glass fiber provided in the first insulating layer 111 from being exposed, thereby improving the circuit integration and resolving electrical reliability and/or mechanical reliability problems due to the exposure of the glass fiber. This will be described in more detail below.

In addition, the first embodiment uses a barrier layer 121BR to provide the first recess portion 112R and the metal layer 121BP of the reinforcing portion, through which deformation in the horizontal direction and deformation in the vertical direction of the circuit board and the semiconductor package can be minimized.

In addition, since the embodiment does not have to consider damage to the first insulating layer 111 by the barrier layer in the de-smear process, it may be advantageous in selecting conditions of the de-smear process. Through this, the embodiment may improve the adhesion between the second circuit pattern layer 122 disposed on the second insulating layer 112 and the second insulating layer 112. Specifically, the cavity 150 may be formed together with the through hole in a process of forming the through hole corresponding to the second through electrode 132 in the second insulating layer 112. Through this, the embodiment may be advantageous in selecting the conditions of the de-smear process, and thus the de-smear process may be performed under conditions capable of improving the adhesion with the second circuit pattern layer 122. Through this, the embodiment can improve the adhesion between the second insulating layer 112 and the second circuit pattern layer 122.

The circuit board of the embodiment can include a through electrode. The through electrode can electrically connect circuit pattern layers disposed in different layers to each other. The through electrode can also be referred to a ‘via’.

The through electrode penetrates the first insulating layer 111 and the second insulating layer 112 included in the circuit board, and thus can electrically connect circuit patterns disposed in different layers. At this time, the through electrode can be formed by penetrating only one insulating layer, or differently, the through electrode can be formed by commonly penetrating at least two or more insulating layers.

For example, the circuit board includes a first through electrode 131. The first through electrode 131 can be formed by penetrating the first insulating layer 111. The first through electrode 131 can electrically connect between the first circuit pattern layer 121 and the third circuit pattern layer 123. For example, an upper surface of the first through electrode 131 can be directly connected to a lower surface of the first circuit pattern layer 121. For example, a lower surface of the first through electrode 131 can be directly connected to the third circuit pattern layer 123.

Accordingly, the first circuit pattern layer 121 and the third circuit pattern layer 123 can be electrically connected to each other through the first through electrode 131 to transmit a signal.

At this time, the first through electrode 131 can include a first through part 131a connected to the first pad 121-1 and a second through part connected to the second pad 121-2.

In addition, the circuit board can include a second through electrode 132. The second through electrode 132 may be formed by penetrating the second insulating layer 112. The second through electrode 132 may electrically connect the first circuit pattern layer 121 and the second circuit pattern layer 122. For example, a lower surface of the second through electrode 132 may be directly connected to the first circuit pattern layer 121. For example, an upper surface of the second through electrode 132 may be directly connected to the second circuit pattern layer 122. Accordingly, the first circuit pattern layer 121 and the second circuit pattern layer 122 may be directly electrically connected to each other through the second through electrode 132 to transmit a signal.

The first through electrode 131 and the second through electrode 132 may be formed by forming a through hole penetrating the first insulating layer 111 and the second insulating layer 112 and filling the inside of the formed through hole with a conductive material.

Meanwhile, the circuit board of the embodiment may include a first protective layer 141 and a second protective layer 142. The first protective layer 141 and the second protective layer 142 may be disposed at an outermost side of the circuit board.

For example, the first protective layer 141 may be disposed at a first outermost or lowermost side of the circuit board. For example, the first protective layer 141 may be disposed on the lower surface of the first insulating layer 111.

For example, the second protective layer 142 may be disposed at a second outermost or uppermost side of the circuit board. For example, the second protective layer 142 may be disposed on the upper surface of the second insulating layer 112.

The first protective layer 141 may include at least one opening (not shown). For example, the first protective layer 141 may include an opening vertically overlapping at least one of the third circuit pattern layers 123. For example, the first protective layer 141 may include an opening vertically overlapping a terminal pad (not shown) of the third circuit pattern layer 123 on which a conductive bonding part for connection with an external substrate is to be disposed.

The second protective layer 142 may include at least one opening (not shown). For example, the second protective layer 142 may include an opening vertically overlapping at least one of the second circuit pattern layers 122. For example, the second protective layer 142 may include an opening that vertically overlaps with a terminal pad (not shown) of the second circuit pattern layer 122 on which a conductive bonding part for connection with a memory substrate or an interposer substrate is disposed. In addition, the second protective layer 142 may include a through hole (not shown) that vertically overlaps with a cavity 121 of the second insulating layer 112.

Meanwhile, a process of providing a reinforcing portion including a first recess portion 112R and a metal layer 121BP according to the first embodiment is described as follows.

As illustrated in FIG. 2, the first insulating layer 111, the second insulating layer 112, and the cavity 150 provided in the second insulating layer 112 are schematically described. A first circuit pattern layer 121 including a first pad 121-1 and a second pad 121-2 spaced apart from each other along the horizontal direction may be provided on the first insulating layer 111.

The first pad 121-1 may be provided in multiple numbers on the first region R1 of the first insulating layer 111 spaced apart from each other along the horizontal direction. The second pad 121-2 may be physically spaced apart from the first pad 121-1, and may be provided in multiple numbers on the second region R2 of the first insulating layer 111 spaced apart from each other along the horizontal direction.

A second insulating layer 112 may be disposed on the first insulating layer 111. The second insulating layer 112 may be provided with a cavity 150 penetrating the upper surface of the second insulating layer 112 and the lower surface of the second insulating layer 112. A planar shape of the cavity 150 may be a square shape, but is not limited thereto. For example, the planar shape of the cavity 150 may have a triangular shape, a circular shape, an oval shape, a polygonal shape, etc.

The side wall 150S of the cavity 150 of the second insulating layer 112 may be divided into a plurality of parts. For example, when the planar shape of the cavity 150 is a square shape, the side wall 150S can be divided into first to fourth parts 150S1, 150S2, 150S3, and 150S4 corresponding to the square shape.

At this time, a barrier layer 121BR is provided on the first insulating layer 111 before the cavity 150 is formed. An outer width of the barrier layer 121BR can be larger than a width of the cavity 150. Therefore, the barrier layer 121BR can include a first portion 121BR1 that vertically overlaps the cavity 150 and a second portion 121BR2 that does not overlap the cavity 150 in a vertical direction.

At this time, the barrier layer 121BR has a concave portion 121BC. The concave portion 121BC is provided concavely toward an inner direction from the outer surface of the barrier layer 121BR. In addition, the concave portions 121BC are provided in multiple numbers while being spaced apart from each other along the circumferential direction of the outer surface of the barrier layer 121BR. At least a part of the concave portions 121BC may be provided in the first portion 121BR1 of the barrier layer 121BR, and a remaining part may be provided in the second portion 121BR2 of the barrier layer 121BR.

The barrier layer 121BR may be a stopper used to form a cavity 150 in the second insulating layer 112. Alternatively, the barrier layer 121BR may be a protective part for protecting the upper surface of the first insulating layer 111 in the process of de-smearing the second insulating layer 112 after the cavity 150 is formed.

Therefore, the first region R1 of the first insulating layer 111 may be divided into a plurality of parts. For example, the first region R1 may include a first part R1-1 that vertically overlaps with the first portion 121BR1 of the barrier layer 121BR and a second part R1-2 that vertically overlaps with the concave portion 121BC without vertically overlapping with the first portion 121BR1 of the barrier layer 121BR. At this time, in one embodiment, a width or de-smear condition of the concave portion 121BC may be adjusted so that the de-smear of the second part R1-2 of the first insulating layer 111 is not performed in the de-smear process. However, the embodiment is not limited thereto. For example, the de-smear of the second part R1-2 of the first insulating layer 111 may be performed in the de-smear process, and accordingly, the second part R1-2 of the first insulating layer 111 may be provided with a second recess portion (to be described later) that is concave in the vertical direction.

In addition, referring to FIGS. 3 and 4, when the formation of the cavity 150 and the de-smear process are completed while the barrier layer 121BR is disposed, a process of removing a portion of the barrier layer 121BR by etching is performed.

At this time, the first portion 121BR1 of the barrier layer 121BR vertically overlaps with the cavity 150, and thus can be entirely removed in the etching process.

In addition, the second portion 121BR2 of the barrier layer 121BR can be partially removed as over-etching is performed in the process of removing the first portion 121BR1. At this time, the barrier layer 121BR is provided with a concave portion 121BC. Accordingly, the second insulating layer 112 can be provided with a first recess portion 112R as a result of over-etching of the second portion 121BR2 of the barrier layer 121BR. At this time, the second portion 121BR2 of the barrier layer 121BR may be provided with a plurality of parts spaced apart along the circumferential direction of the barrier layer 121BR by the concave portion 121BC, and accordingly, the first recess portion 112R may include a plurality of first recesses spaced apart from each other along the circumferential direction of the cavity 150.

In addition, a part of the second portion 121BR2 of the barrier layer 121BR may not be removed in the etching process. Accordingly, a metal layer 121BP including a plurality of metal patterns each corresponding to a plurality of first recesses of the first recess portion 112R along the circumferential direction of the first recess portion 112R may be provided.

At this time, the first recess portion 112R is formed by etching the barrier layer 121BR and may have a shape corresponding to a shape of the barrier layer 121BR. For example, a vertical cross-sectional shape of the first recess portion 112R may have a square shape.

In summary, the barrier layer 121BR includes a first portion 121BR1 and a second portion 121BR2, and the second portion 121BR2 is divided into a plurality of parts spaced apart from each other along the circumferential direction of the outer surface of the barrier layer 121BR by the concave portion 121BC. Therefore, when etching the second portion 121BR2 of the barrier layer 121BR is performed, a first recess portion 112R including a plurality of first recesses and a metal layer 121BP including a plurality of metal patterns may be provided corresponding to a plurality of parts of the second portion 121BR2 of the barrier layer 121BR.

In addition, referring to FIGS. 4 and 5, the first pad 121-1 and the second pad 121-2 of the first circuit pattern layer 121 of the embodiment may have a same layer structure. At this time, although not shown in the drawing, the second circuit pattern layer 122, the third circuit pattern layer 123, the first through electrode 131, and the second through electrode 132 may also have layer structures corresponding to the first pad 121-1 and the second pad 121-2 described below.

The first circuit pattern layer 121 includes a plurality of layers.

The first circuit pattern layer 121 includes a first layer 121a disposed on the first insulating layer 111. The first layer 121a may mean a seed layer for electroplating the second layer 121b of the first circuit pattern layer 121.

For example, the first layer 121a may be a chemical copper plating layer. For example, the first layer 121a may be a copper foil layer (Cu foil).

In one embodiment, the first layer 121a may include only one of the chemical copper plating layer and the copper foil layer.

In another embodiment, the first layer 121a may include both the chemical copper plating layer and the copper foil layer.

A thickness T1 of the first layer 121a can satisfy a range of 0.5 μm to 3.0 μm. Preferably, the thickness T1 of the first layer 121a can satisfy a range of 0.7 μm to 2.8 μm. More preferably, the thickness T1 of the first layer 121a can satisfy a range of 0.8 μm to 2.5 μm.

If the thickness T1 of the first layer 121a is less than 0.5 μm, the first layer 121a may not function as a seed layer. If the thickness T1 of the first layer 121a is less than 0.5 μm, it may be difficult to form a first layer 121a with a uniform thickness on the upper surface of the first insulating layer 111.

If the thickness T1 of the first layer 121a exceeds 3.0 μm, a time required to etch the first layer 121a may increase. If the thickness T1 of the first layer 121a exceeds 3.0 μm, the second layer 121 b may be deformed during the etching of the first layer 121a. The deformed second layer 121b may mean that a difference between a width of the upper surface and a width of the lower surface of the second layer 121b increases as a side portion of the first layer 121a is also etched.

The second layer 121b may be disposed on the first layer 121a. The second layer 121b may be an electrolytic plating layer that is electrolytically plated using the first layer 121a as a seed layer.

A thickness of the second layer 121b may correspond to a value obtained by subtracting the thickness T1 of the first layer 121a from a total thickness of the first circuit pattern layer 121. Since the total thickness of the first circuit pattern layer 121 has already been described above, a detailed description thereof will be omitted.

Meanwhile, each of the first pad 121-1 and the second pad 121-2 of the first circuit pattern layer 121 may include the first layer 121a and the second layer 121b. At this time, the first pad 121-1 and the second pad 121-2 include a same first layer 121a and a same second layer 121b, and may be distinguished according to the arrangement position and function.

A width W1 of the first pad 121-1 in the horizontal direction can satisfy a range of 40 μm to 70 μm. Preferably, the width W1 of the first pad 121-1 in the horizontal direction can satisfy a range of 42 μm to 68 μm. More preferably, the width W1 of the first pad 121-1 in the horizontal direction can satisfy a range of 45 μm to 65 μm.

If the width W1 of the first pad 121-1 is smaller than 40 μm, a connection member (e.g., a semiconductor device) may not be stably mounted on the first pad 121-1. For example, if the width W1 of the first pad 121-1 is smaller than 40 μm, the amount of conductive adhesive material (e.g., solder) disposed on the first pad 121-1 may decrease, and thus the bonding strength between the first pad 121-1 and the connection member may decrease.

If the width W1 of the first pad 121-1 is larger than 70 μm, an area of the cavity 150 may increase corresponding to the width of the first pad 121-1, and thereby the circuit integration may decrease, or the area of the circuit board and the semiconductor package may increase.

The first recess portion 112R may be provided concavely in a direction toward the outer surface of the second insulating layer 112 (or in a direction away from the cavity) at the lower end of the side wall 150S of the cavity 150 of the second insulating layer 112. For example, the first recess portion 112R may be provided concavely in a horizontal direction in the second insulating layer 112.

A vertical distance of the first recess portion 112R may correspond to a thickness T1 of the first layer 121a of the first pad 121-1. For example, the barrier layer 121BR may be a part of the first layer 121a provided entirely on the first insulating layer 111 in the manufacturing process of the first circuit pattern layer. Accordingly, the barrier layer 121BR may have a thickness corresponding to the first layer 121a. Accordingly, the vertical distance of the first recess portion 112R may correspond to the thickness T1 of the first layer 121a of the first pad 121-1.

A vertical distance of the first recess portion 112R may satisfy a range of 0.5 μm to 3.0 μm. Preferably, the vertical distance of the first recess portion 112R may satisfy a range of 0.7 μm to 2.8 μm. More preferably, the vertical distance of the first recess portion 112R may satisfy a range of 0.8 μm to 2.5 μm.

A width W2 of the first recess portion 112R in the horizontal direction may correspond to a vertical distance of the first recess portion 112R. That is, the first recess portion 112R may be formed by etching a portion of the second portion 121BR2 of the barrier layer 121BR covered with the second insulating layer 112 after the formation of the cavity 150. Accordingly, the width W2 of the first recess portion 112R in the horizontal direction may correspond to the vertical distance of the first recess portion 112R. For example, the width W2 of the first recess portion 112R in the horizontal direction may satisfy a range of 0.5 μm to 3.0 μm. Preferably, the width W2 of the first recess portion 112R in the horizontal direction may satisfy a range of 0.7 μm to 2.8 μm. More preferably, the width W2 of the first recess portion 112R in the horizontal direction may satisfy a range of 0.8 μm to 2.5 μm.

However, considering a process deviation in a process of etching the entire first portion 121BR1 and a part of the second portion 121BR2 of the barrier layer 121BR, the width W2 of the first recess portion 112R in the horizontal direction may be smaller than the vertical distance of the first recess portion 112R. For example, the width W2 of the first recess portion 112R in the horizontal direction may satisfy a range of 50% to 95% of the vertical distance of the first recess portion 112R or the thickness T1 of the first layer 121a. For example, the width W2 of the first recess portion 112R in the horizontal direction may satisfy a range of 55% to 92% of the vertical distance of the first recess portion 112R or the thickness T1 of the first layer 121a. For example, the width W2 of the first recess portion 112R in the horizontal direction may satisfy a range of 60% to 90% of the vertical distance of the first recess portion 112R or the thickness T1 of the first layer 121a.

For example, if the width W2 of the first recess portion 112R in the horizontal direction is smaller than 50% of the vertical distance of the first recess portion 112R or the thickness T1 of the first layer 121a, the effect of preventing warpage of the circuit board and semiconductor package exhibited by the first recess portion 112R may be insufficient. Furthermore, under the condition of over-etching the barrier layer 121BR, it may be difficult for the width W2 of the first recess portion 112R in the horizontal direction to be formed to be greater than 95% of the vertical distance of the first recess portion 112R or the thickness T1 of the first layer 121a.

Meanwhile, the width W1 of the first pad 121-1 may be greater than the thickness T1 of the first layer 121a. In addition, the width W1 of the first pad 121-1 may be greater than the vertical distance of the first recess portion 112R. In addition, the width W1 of the first pad 121-1 may be greater than the width W2 of the first recess portion 112R in the horizontal direction.

For example, the width W1 of the first pad 121-1 may be 35 times or more, 40 times or more, or 45 times or more the thickness T1 of the first layer 121a. In addition, the width W1 of the first pad 121-1 may be 35 times or more, 40 times or more, or 45 times or more the vertical distance of the first recess portion 112R. In addition, the width W1 of the first pad 121-1 may be 35 times or more, 40 times or more, or 45 times or more the width W2 of the first recess portion 112R in the horizontal direction. That is, the thickness T1 of the first layer 121a, the vertical distance of the first recess portion 112R, and the width W2 of the first recess portion 112R in the horizontal direction can have corresponding values, and thus can satisfy the relationship with the width W1 of the first pad 121-1. Through this, the embodiment can maximize the effect exhibited by the first recess portion 112R while improving the circuit integration and improving the physical reliability and electrical reliability.

In addition, the metal layer 121BP can be provided along the first recess portion 112R. The width W3 of the metal layer 121BP in the horizontal direction can satisfy a range of 1.0 μm to 7.0 μm. Preferably, the width W3 of the metal layer 121BP in the horizontal direction can satisfy a range of 1.5 μm to 6.5 μm. More preferably, the width W3 of the metal layer 121BP in the horizontal direction can satisfy a range of 2.0 μm to 6.0 μm.

The metal layer 121BP may be provided adjacent to the first recess portion 112R, and thus may function as a reinforcing member that prevents warpage of the circuit board and the semiconductor package in the vertical direction while preventing thermal expansion or thermal contraction in the horizontal direction.

The width W3 of the metal layer 121BP in the horizontal direction may be greater than the width W2 of the first recess portion 112R in the horizontal direction. At this time, when the first recess portion 112R is provided, thermal expansion and/or thermal contraction may be alleviated, but warpage in the vertical direction may occur due to this. Therefore, the width W3 of the metal layer 121BP in the horizontal direction may be greater than the width W2 of the first recess portion 112R in the horizontal direction, and thus, warpage in the vertical direction may be minimized while alleviating thermal expansion and/or thermal contraction.

The metal layer 121BP is disposed along the circumference of the first recess portion 112R, and accordingly, at least a portion of a side surface of the metal layer 121BP may be exposed through the first recess portion 112R. For example, the first recess portion 112R may include a plurality of first recesses provided along the circumferential direction of an inner surface of the plurality of metal patterns of the metal layer 121BP. For example, the side surface of the metal layer 121BP may overlap the first recess portion 112R in the horizontal direction and may not be covered by the second insulating layer 112.

Furthermore, the metal layer 121BP includes a plurality of metal patterns spaced apart from each other along the circumferential direction of the lower end of the side wall of the cavity 150. At this time, each of the plurality of metal patterns of the metal layer 121BP may have a same width W3 in the horizontal direction as illustrated in FIG. 4, but is not limited thereto.

For example, the plurality of metal patterns of the metal layer 121BP may have different widths in the horizontal direction. For example, the metal layer 121BP may have different widths in the horizontal direction along the circumferential direction of the first recess portion 112R, thereby more effectively preventing the circuit board from being significantly bent in a specific direction.

For example, the second pad 121-2 may be provided with different densities along the circumferential direction of the lower end of the side wall 150S of the cavity 150. For example, the density of the second pad adjacent to the first part of the side wall of the cavity 150 may be greater than the density of the second pad adjacent to the second part opposite to the first part. In this case, the embodiment may be configured such that a metal pattern having a width in the horizontal direction of a third-first width is provided in the circumferential direction of the first part of the side wall of the cavity 150, and a metal pattern having a width in the horizontal direction of a third-second width, which is larger than the third-first width, is provided in the circumferential direction of the second part of the side wall of the cavity 150.

Through this, the embodiment may be configured such that the metal density by region is uniform by using the metal layer 121BP, and thus warping of the circuit board may be further prevented.

In addition, the plurality of metal patterns of the metal layer 121BP may be spaced apart from each other at a predetermined spacing W4.

The spacing W4 between the plurality of metal patterns of the metal layer 121BP may satisfy a range of 2 μm to 12 μm. Preferably, the spacing W4 between the plurality of metal patterns of the metal layer 121BP can satisfy a range of 2.5 μm to 11.5 μm. More preferably, the spacing W4 between the plurality of metal patterns of the metal layer 121BP can satisfy a range of 3 μm to 11 μm.

If the spacing W4 between the plurality of metal patterns of the metal layer 121BP is smaller than 2 μm, the warpage of the circuit board in the vertical direction may increase, and thus the physical reliability of the circuit board may deteriorate. If the spacing W4 between the plurality of metal patterns of the metal layer 121BP is smaller than 2 μm, it may be difficult to arrange a connection pattern (221-3 of FIG. 8) that directly connects the first pad and the second pad on the first insulating layer 111. For example, if the spacing W4 between the plurality of metal patterns of the metal layer 121BP is smaller than 2 μm, at least two of the plurality of metal patterns may be electrically connected to each other due to a process error in the process of forming the plurality of metal patterns, and an electrical short problem may occur in which the plurality of connection patterns 221-3 are electrically connected to each other by the metal patterns.

In addition, if the spacing W4 between the plurality of metal patterns of the metal layer 121BP is larger than 12 μm, the adhesion between the first insulating layer 111 and the second insulating layer 112 may be reduced, and thus, a mechanical reliability problem in which the second insulating layer 112 is peeled off from the first insulating layer 111 may occur. In addition, if the spacing W4 between the plurality of metal patterns of the metal layer 121BP is larger than 12 μm, the mechanical and/or electrical reliability improvement effect exhibited by the metal layer 121BP may be insufficient.

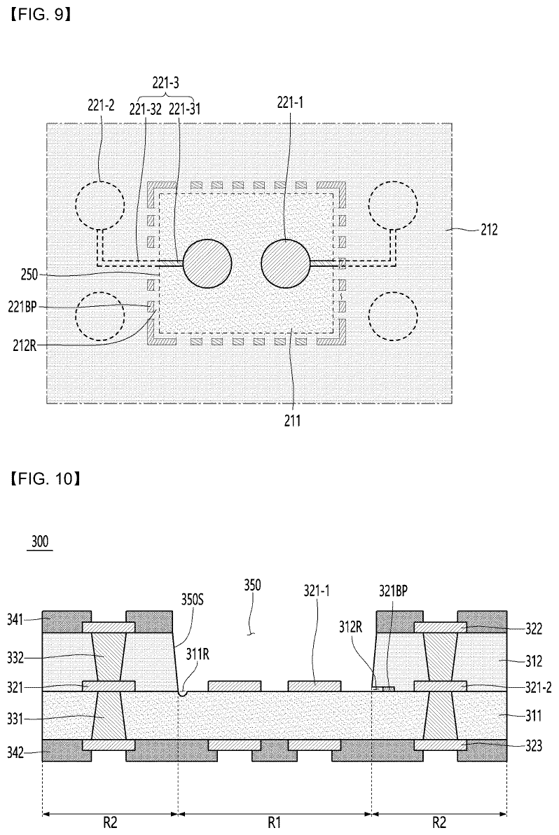

FIG. 6 is a cross-sectional view showing a circuit board according to a second embodiment.

Referring to FIG. 6, the circuit board 100A of the second embodiment includes a first insulating layer 111, a second insulating layer 112, a first circuit pattern layer 121, a second circuit pattern layer 122, a third circuit pattern layer 123, a first through electrode 131, a second through electrode 132, a first protective layer 141, and a second protective layer 142.

In addition, the circuit board 100A of the second embodiment includes a reinforcing portion.

At this time, the reinforcing portion in the circuit board of the first embodiment includes a first recess portion 112R and a metal layer 121BP provided along the circumferential direction of the lower end of the side wall 150S of the cavity 150.

In contrast, the reinforcing portion of the circuit board 100A of the second embodiment may include only the first recess portion 112R.

For example, in the first embodiment, a part of the second portion 121BR2 of the barrier layer 121BR is removed to provide a reinforcing portion including the first recess portion 112R and the metal layer 121BP.

In contrast, in the second embodiment, the second portion 121BR2 of the barrier layer 121BR is entirely removed. As a result, the circuit board of the second embodiment may include only the first recess portion 112R formed by the entire removal of the second portion 121BR2 of the barrier layer 121BR.

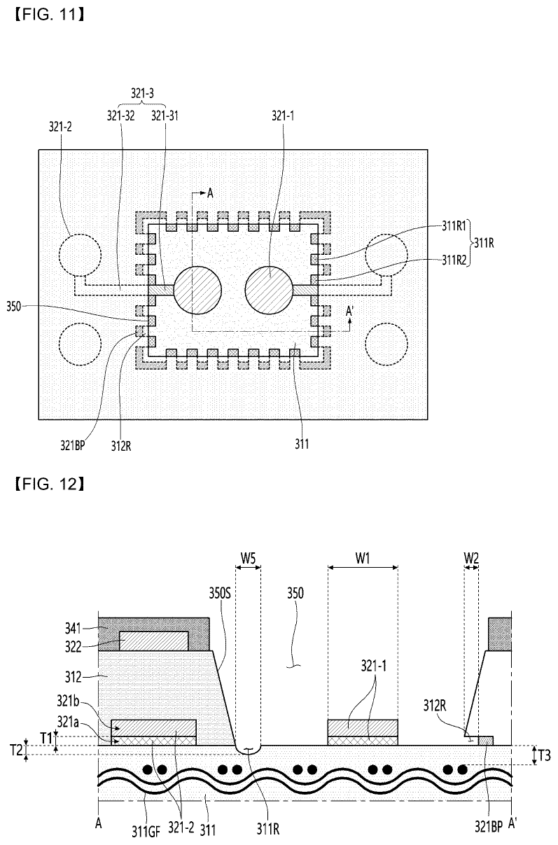

FIG. 7 is a cross-sectional view showing a circuit board according to the third embodiment.

Referring to FIG. 7, the circuit board 100A of the third embodiment includes a first insulating layer 111, a second insulating layer 112, a first circuit pattern layer 121, a second circuit pattern layer 122, a third circuit pattern layer 123, a first through electrode 131, a second through electrode 132, a first protective layer 141, and a second protective layer 142.

In addition, the circuit board 100B of the third embodiment includes a reinforcing portion.

At this time, the reinforcing portion in the circuit board of the first embodiment includes a first recess portion 112R provided along the circumferential direction of the lower end of the side wall 150S of the cavity 150 and a metal layer 121BP. In addition, the reinforcing portion in the circuit board of the second embodiment includes a first recess portion 112R provided along the circumferential direction of the lower end of the side wall 150S of the cavity 150.

In contrast, the reinforcing portion of the circuit board 100B of the third embodiment may include only the metal layer 121BP.

For example, in the first embodiment, a part of the second portion 121BR2 of the barrier layer 121BR is removed to provide a reinforcing portion including the first recess portion 112R and the metal layer 121BP. In addition, in the second embodiment, the second portion 121BR2 of the barrier layer 121BR is entirely removed to provide a reinforcing member including only the first recess portion 112R.

In contrast, in the third embodiment, only the first portion 121BR1 of the barrier layer 121BR is selectively removed without removing the second portion 121BR2 of the barrier layer 121BR. Through this, the circuit board of the second embodiment can provide a reinforcing member including only the metal layer 121BP since the second portion 121BR2 of the barrier layer 121BR is not removed.

Therefore, the metal layer 121BP in the first embodiment is provided at a certain distance from the lower end of the side of the cavity 150 in a direction toward an outside of the second insulating layer 112.

In contrast, the metal layer 121BP of the third embodiment may not be separated from the lower end of the side of the cavity 150, and further, a side surface of the metal layer 121BP may be directly connected to the lower end of the side surface of the cavity 150.

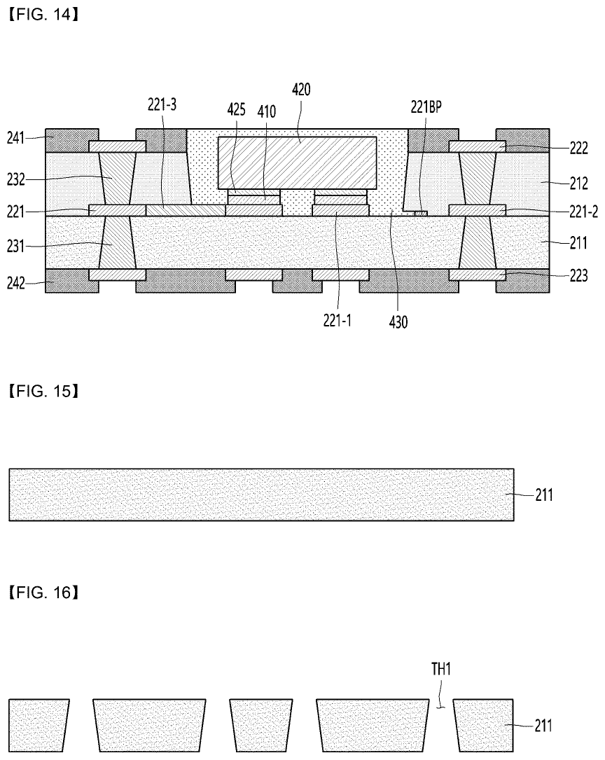

FIG. 8 is a cross-sectional view showing a circuit board according to a fourth embodiment, and FIG. 9 is a drawing showing a plan view of the circuit board of FIG. 8.

Referring to FIGS. 8 and 9, the circuit board 200 of the fourth embodiment includes a first insulating layer 211, a second insulating layer 212, a first circuit pattern layer 221, a second circuit pattern layer 222, a third circuit pattern layer 223, a first through electrode 231, a second through electrode 232, a first protective layer 241, and a second protective layer 242.

In addition, the second insulating layer 212 may include a cavity 250.

In addition, the first circuit pattern layer 221 may include a first pad 221-1 and a second pad 222-2.

At this time, the circuit board of the fourth embodiment may be different from the circuit board of the first embodiment in that the first circuit pattern layer 221 is further provided with a connection pattern 221-3.

The connection pattern 221-3 may directly connect the first pad 221-1 and the second pad 221-2 of the first circuit pattern layer 221.

One end of the connection pattern 221-3 may be connected to the first pad 221-1, and another end of the connection pattern 221-3 may be connected to the second pad 221-2. The first pad 221-1 may be provided in multiple numbers, and accordingly, the connection pattern 221-3 may also be provided in multiple numbers corresponding to the number of the first pad 221-1.

The connection pattern 221-3 may include a first pattern region 221-31 that overlaps the cavity 250 in a vertical direction. An end of the first pattern region 221-31 of the connection pattern 221-3 may be connected to the first pad 221-1.

The connection pattern 221-3 may include a second pattern region 221-32 that does not overlap the cavity 250 in a vertical direction. An end of the second pattern region 221-32 of the connection pattern 221-3 may be connected to the second pad 221-2.

The connection pattern 221-3 may not be connected to the reinforcement part provided along the circumferential direction of the lower end of the side wall 250S of the cavity 250. For example, the connection pattern 221-3 may not be connected to the metal layer 221BP of the reinforcing part. That is, the metal layer 221BP may have a plurality of metal patterns, and the plurality of metal patterns may be provided while avoiding a region where the connection pattern 221-3 is disposed at the lower end of the side wall 250S of the cavity 250. For example, the connection pattern 221-3 may be disposed across a separation region between the plurality of metal patterns of the metal layer 221BP on the first insulating layer 211.

At this time, the metal layer 221BP of the embodiment has a plurality of metal patterns provided along the circumferential direction of the lower end of the side wall 250S of the cavity 250. Accordingly, the embodiment can arrange a connection pattern 221-3 that directly connects the first pad 221-1 and the second pad 221-2 on the first insulating layer 211.

For example, according to the conventional technology, when a stopper is used, the metal layer is provided with a closed loop shape along the circumferential direction, and therefore, it was impossible to arrange the connection pattern. For example, when the connection pattern is disposed in the conventional technology, a plurality of adjacent connection patterns are electrically connected by the stopper having the closed loop shape, and thus, an electrical short problem occurs.

In contrast, the embodiment changes the shape of the barrier layer 121BR so that the metal layer 221BP includes a plurality of metal patterns that are spaced apart from each other along the circumferential direction. Through this, the embodiment can solve the reliability problem that the plurality of connection patterns are electrically connected between the plurality of connection patterns by the metal patterns that are separated from each other even when the plurality of connection patterns are disposed on the first insulating layer 211.

Furthermore, although the drawing illustrates that the connection pattern 221-3 is not connected to the first recess portion 212R and the metal layer 221BP of the reinforcement, it is not limited thereto. For example, at least a part of the connection pattern 221-3 may be connected to the first recess portion 112R and the metal layer 221BP. However, when a plurality of connection patterns are provided, each of the plurality of connection patterns may be connected to different first recesses and metal patterns, and thus the plurality of connection patterns may be electrically isolated from each other.

For example, the metal layer 221BP may include a first metal pattern and a second metal pattern that are spaced apart from each other, and the connection pattern 221-3 may include a first connection pattern and a second connection pattern that are spaced apart from each other. At this time, the first connection pattern may be connected to the first metal pattern, and the second connection pattern may be connected to the second metal pattern. However, the first metal pattern and the second metal pattern are electrically isolated from each other, and accordingly, the first connection pattern and the second connection pattern can also be electrically isolated from each other.

Specifically, as illustrated in FIG. 9, one of the plurality of connection patterns 221-3 may overlap one of the plurality of metal patterns of the metal layer 221BP in the vertical direction. For example, the first layer, which is a seed layer of at least one of the plurality of connection patterns 221-3, may include a portion whose width changes along an extension direction of the connection pattern 221-3. In addition, a portion whose width changes may correspond to a portion where the metal pattern of the metal layer 221BP is disposed.

In addition, according to the fourth embodiment, among the first through electrodes 231 penetrating the first insulating layer 211, the first through part 131a of FIG. 1 may be omitted. For example, if the connection pattern 221-3 is not provided, in order to electrically connect the first pad 221-1 and the second pad 221-2, a first through electrode that overlaps the first pad 221-1 in the vertical direction must be provided.

In contrast, the embodiment can directly connect the first pad 221-1 and the second pad 221-2 using the connection pattern 221-3, and thus the first through electrode that overlaps the first pad 221-1 in the vertical direction can be omitted. Furthermore, the embodiment can reduce a length of a signal line between the first pad 221-1 and the second pad 221-2 by directly connecting them using the connection pattern 221-3. For example, the signal line including the connection pattern 221-3 can be shorter than the signal line including the first through electrode. Therefore, the embodiment can minimize signal transmission loss by reducing the signal transmission line between the first pad 221-1 and the second pad 221-2, thereby improving electrical characteristics.

Therefore, the embodiment can arrange a connection pattern 221-3 that directly connects the first pad 221-1 and the second pad 221-2 on the first insulating layer 211 while arranging a reinforcing portion including the first recess portion 212R and the metal layer 221BP. Therefore, the embodiment can directly connect the first pad and the second pad using the connection pattern, thereby improving the circuit integration. Therefore, the embodiment can minimize signal transmission loss by reducing the signal transmission line between the first pad 221-1 and the second pad 221-2, thereby improving electrical characteristics.

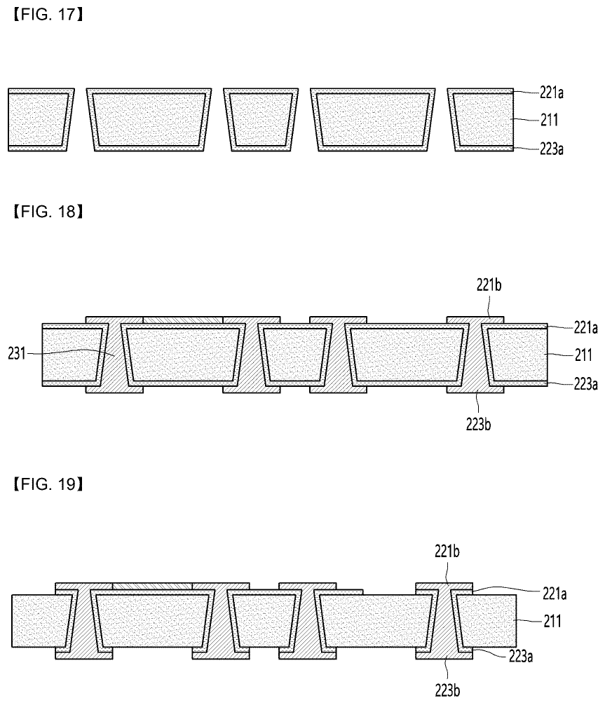

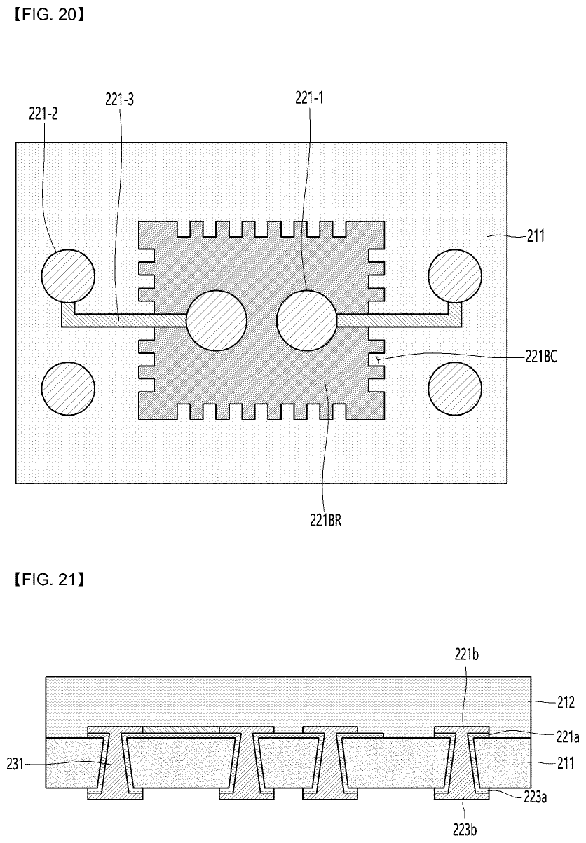

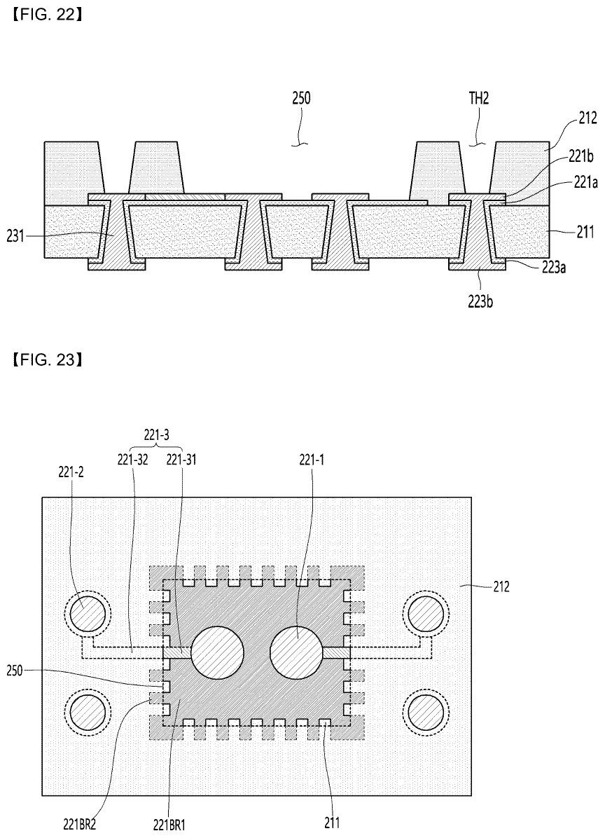

FIG. 10 is a cross-sectional view showing a circuit board according to a fifth embodiment, FIG. 11 is a plan view of the circuit board of FIG. 10, and FIG. 12 is an enlarged view of a part of the circuit board of FIG. 10.

Referring to FIGS. 10 to 12, the circuit board 300 of the fifth embodiment includes a first insulating layer 311, a second insulating layer 312, a first circuit pattern layer 321, a second circuit pattern layer 322, a third circuit pattern layer 323, a first through electrode 331, a second through electrode 332, a first protective layer 341, and a second protective layer 342.

In addition, the second insulating layer 312 may include a cavity 350.

In addition, the first circuit pattern layer 321 may include a first pad 321-1, a second pad 322-2, and a connection pattern 321-3.

At this time, the circuit board of the fifth embodiment may be different from the circuit board of the fourth embodiment in that a second recess portion 311R is further provided on the upper surface of the first insulating layer 311.

The second recess portion 311R may be provided on the upper surface of the first insulating layer 311.

That is, the circuit board of the fifth embodiment may include a first recess portion 312R provided on the second insulating layer 312 and a second recess portion 311R provided on the first insulating layer 311.

Each of the first recess portion 312R and the second recess portion 311R may be connected to the lower end of the side wall 350S of the cavity 350.

For example, a part of the lower end of the side wall 350S of the cavity 350 may be connected to the first recess portion 312R, and a remaining part of the lower end of the side wall 350S of the cavity 350 may be connected to the second recess portion 311R.

At this time, the first recess portion 312R includes a plurality of first recesses concavely provided in the horizontal direction in the second insulating layer 312 as described in the previous embodiment.

In addition, the second recess portion 311R includes second recesses concavely provided in the vertical direction in the upper surface of the first insulating layer 311.

The second recess portion 311R may be provided in an edge region of the first region R1 of the first insulating layer 311. For example, the second recess portion 311R may be provided in the edge region of the bottom surface of the cavity 350. That is, the second recess portion 311R may be provided on the upper surface of the first insulating layer 311 connected to the lower end of the side wall 350S of the cavity 350. The second recess portion 311R may be provided concavely from the upper surface toward the lower surface of the first insulating layer 311.

The second recess portion 311R may be provided on the upper surface of the first insulating layer 311 by a de-smear process performed after forming the cavity 350 in the second insulating layer 312.

For example, the barrier layer 121BR has a concave portion 121BC, and at least a portion of the concave portion 121BC overlaps the cavity 350 in the vertical direction. Therefore, when the de-smear process is performed with the barrier layer 121BR disposed, a portion of the upper surface of the first insulating layer 311 may be exposed to an outside through the concave portion 121BC. At this time, the embodiment may prevent the second recess portion 311R from being formed in the de-smear process by adjusting the width of the concave portion 121BC, or may cause the second recess portion 311R to be formed on the upper surface of the first insulating layer 311. The second recess portion 311R may be formed corresponding to the concave portion 121BC.

Therefore, according to an embodiment, the second insulating layer 312 may be provided with a first recess portion 312R in the horizontal direction, and the first insulating layer 311 may be provided with a second recess portion 311R in the vertical direction.

Through this, the embodiment can more efficiently distribute the stress acting on the first insulating layer 31 and the second insulating layer 32, thereby improving the warpage characteristics of the circuit board.

For example, the second recess portion 311R may have a function of increasing a surface area of the upper surface of the first insulating layer 311. Accordingly, the second recess portion 311R may alleviate expansion of the circuit board in the horizontal direction due to thermal stress occurring in the manufacturing environment or the usage environment of the circuit board, thereby improving the mechanical reliability and/or physical reliability of the circuit board and the semiconductor package including the circuit board.

In addition, the first recess portion 312R can reduce an area of the interface between the first insulating layer 311 and the second insulating layer 312, thereby dispersing the stress acting on the second insulating layer 312. Therefore, the first recess portion 312R can alleviate a phenomenon in which the circuit board is bent in a specific direction (for example, a phenomenon in which both ends of the circuit board are bent upward or a phenomenon in which both ends of the circuit board are bent downward).

At this time, the first recess portion 312R and the second recess portion 311R can be alternately provided along the circumferential direction of the lower end of the side wall 350S of the cavity 350.

For example, the first recess portion 312R includes a plurality of first recesses, and the second recess portion 311R includes a plurality of second recesses. At this time, a plurality of first recesses and a plurality of second recesses may be alternately disposed along the circumferential direction of the lower end of the side wall 350S of the cavity 350. This is because the second recess portion 311R is a region corresponding to the concave portion 121BC of the barrier layer 121BR, and the first recess portion 312R corresponds to a region excluding the concave portion 121BC in the second portion 121BR2 of the barrier layer 121BR.

In addition, a vertical distance T2 of the second recess portion 311R may satisfy a range of 0.1 μm to 6.0 μm. Preferably, the vertical distance T2 of the second recess portion 311R may satisfy a range of 0.5 μm to 5.5 μm. More preferably, the vertical distance T2 of the second recess portion 311R may satisfy a range of 1.0 μm to 5 μm.

The vertical distance T2 of the second recess portion 311R may mean a vertical distance from an uppermost end of the upper surface of the first insulating layer 311 to a lowermost end of the bottom surface of the second recess portion 311R. If the vertical distance T2 of the second recess portion 311R is smaller than 0.1 μm, the effect of alleviating thermal expansion and/or thermal contraction of the circuit board by the second recess portion 311R may be insufficient. In addition, if the vertical distance T2 of the second recess portion 311R is smaller than 0.1 μm, the adhesion between the second insulating layer 312 and the second circuit pattern layer 322 may be reduced. For example, the second recess portion 311R may be formed in a de-smear process to provide a certain level of surface roughness to the upper surface of the second insulating layer 312 to increase the adhesion between the second insulating layer 312 and the second circuit pattern layer 322. At this time, the vertical distance T2 of the second recess portion 311R being less than 0.1 μm may mean that a certain level or more of surface roughness is not provided to the second insulating layer 312, and accordingly, the adhesion between the second insulating layer 312 and the second circuit pattern layer 322 may be reduced.

If the vertical distance T2 of the second recess portion 311R exceeds 6.0 μm, the surface roughness of the second insulating layer 312 may increase correspondingly, and the surface roughness of the second circuit pattern layer 322 may increase correspondingly to the surface roughness of the second insulating layer 312. In addition, if the surface roughness of the second circuit pattern layer 322 increases, the transmission loss of a signal transmitted through the second circuit pattern layer 322 may increase due to a skin effect. In addition, if the vertical distance T2 of the second recess portion 311R exceeds 6.0 μm, the glass fiber 311GF provided in the first insulating layer 311 may be exposed through the second recess portion 311R, and the mechanical reliability and/or electrical reliability of the circuit board and the semiconductor package may be deteriorated by the exposed glass fiber 311GF.

For example, the vertical distance T2 of the second recess portion 311R may be determined based on a position of the glass fiber 311GF provided in the first insulating layer 311.

For example, a vertical distance T3 from the upper surface of the first insulating layer 311 to an uppermost end of the glass fiber 311GF may be greater than the vertical distance T2 of the second recess portion 311R. For example, the vertical distance T3 from the upper surface of the first insulating layer 311 to the uppermost end of the glass fiber 311GF may satisfy a range of 3 μm to 10 μm. Preferably, the vertical distance T3 may satisfy a range of 3.5 μm to 9.5 μm. More preferably, the vertical distance T3 may satisfy a range of 4.0 μm to 9.0 μm.

If the vertical distance T3 is less than 3.0 μm, the glass fiber 311GF provided in the first insulating layer 311 may be exposed to the outside due to various tolerances occurring in the manufacturing process of the circuit board, which may cause reliability problems. In addition, if the vertical distance T3 is greater than 10 μm, the amount of the glass fiber 311GF provided in the first insulating layer 311 may decrease, or a thickness of the first insulating layer 311 may increase, which may deteriorate the warpage characteristics of the circuit board and the semiconductor package, or increase the volume of the circuit board and the semiconductor package.

For example, the vertical distance T2 of the second recess portion 311R may satisfy a range of 4% to 70% of the vertical distance T3 of the glass fiber 311GF. Preferably, the vertical distance T2 of the second recess portion 311R can satisfy a range of 8% to 65% of the vertical distance T3 of the glass fiber 311GF. More preferably, the vertical distance T2 of the second recess portion 311R can satisfy a range of 10% to 60% of the vertical distance T3 of the glass fiber 311GF.

A width W5 of the second recess portion 311R in the horizontal direction can correspond to a spacing between the plurality of first recesses of the first recess portion 312R and/or a spacing between the plurality of metal patterns of the metal layer 321BP, but is not limited thereto.

At least one of the plurality of second recesses of the second recess portion 311R can be connected to the connection pattern 321-3.

For example, the plurality of second recesses of the second recess portion 311R may include a second-first recess 311R1 provided between the plurality of first recesses and not connected to the connection pattern 321-3. In addition, the second recess portion 311R may include a second-second recess 311R2 connected to the connection pattern 321-3.

For example, the connection pattern 321-3 may include a first pattern region 321-31 that overlaps the cavity 350 in a vertical direction and a second pattern region 321-32 that does not overlap the cavity 350 in a vertical direction. In addition, the second-second recess 311R2 may be connected to at least a portion of a side surface of the second pattern region 221-32 of the connection pattern 321-3.

Through this, the embodiment can more efficiently solve the electrical reliability problem in which a plurality of connection patterns are electrically connected due to process error as the second-second recess 311R2 of the second recess portion 311R is connected to the connection pattern 321-3.

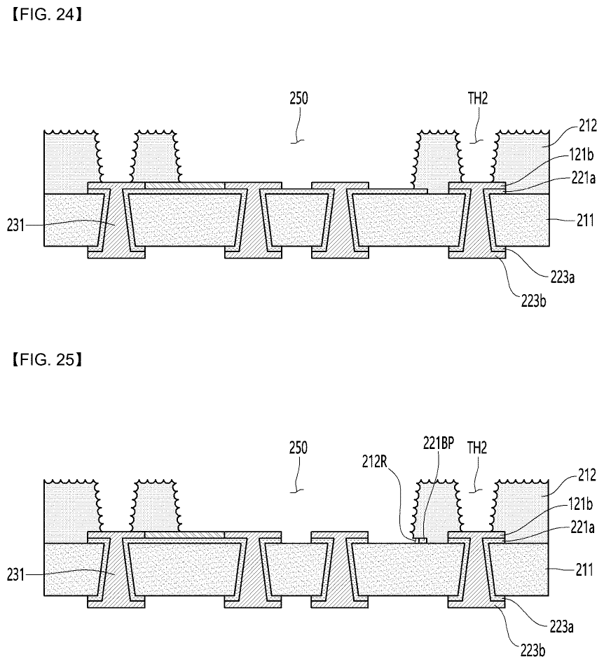

FIG. 13 is a drawing showing the upper surface of the first region of the first insulating layer according to the embodiment and the comparative example.

Referring to (a) of FIG. 13, in the comparative example, the de-smear process is performed in a state where a barrier layer is not provided, and accordingly, the glass fiber 311GF may be exposed through the upper surface of the first region R1 of the first insulating layer 311.

In contrast, referring to (b) of FIG. 13, in the embodiment, the de-smear process is performed in a state where a barrier layer is provided, and accordingly, the glass fiber 311GF may not be exposed through the upper surface of the first region R1 of the first insulating layer 311. For example, only the filler provided in the first insulating layer 311 may be exposed on the upper surface of the first region R1 of the first insulating layer 311.

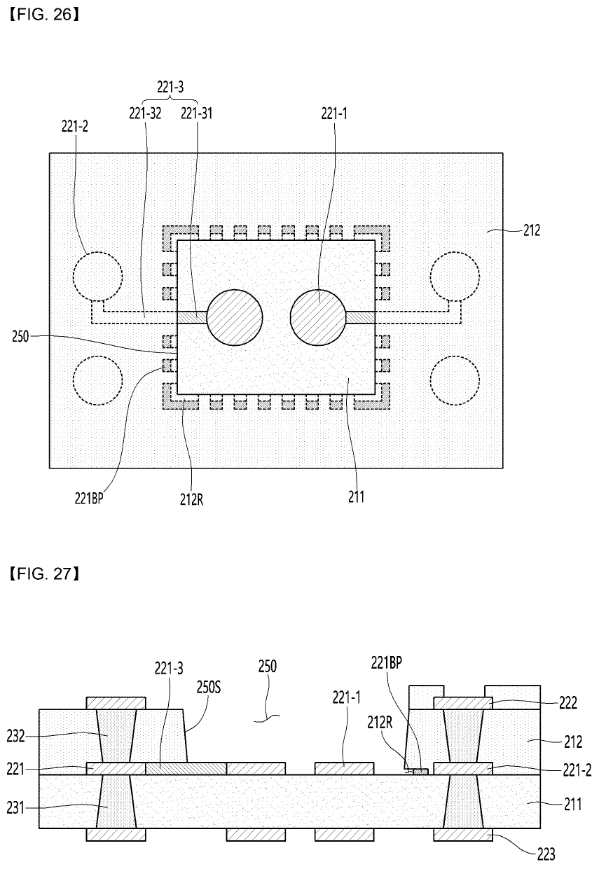

FIG. 14 is a cross-sectional view showing a semiconductor package according to an embodiment.

Referring to FIG. 14, the semiconductor package of the embodiment may include the circuit board of FIG. 8. However, the embodiment is not limited thereto, and the semiconductor package may include any one of the circuit boards of FIGS. 1 to 7 and FIGS. 10 to 12.

The semiconductor package may include a bonding member 410 disposed on the first pad 221-1, and a connection member 420 disposed on the bonding member 410.

The connection member 420 may be any one of a semiconductor device, an interposer, a package substrate, an inorganic bridge, and an organic bridge.

Meanwhile, a molding member 430 may be disposed in the cavity 250. The molding member 430 may be disposed by molding the connection member 420 within the cavity 250.

In addition, the molding member 430 may be provided to fill the first recess portion 212R. At this time, in the case of including the circuit board of FIG. 10, the molding member may be provided to further fill the second recess portion 311R.

The first recess portion 212R may increase a contact area between the molding member 430 and the first insulating layer 211 and the second insulating layer 212. For example, the first recess portion 212R may function as an anchor to improve the bonding strength between the molding member 430 and the first insulating layer 211 and the second insulating layer 212. At least a portion of the molding member 430 may be connected to metal patterns of the metal layer 221BP provided along the first recess portion 212R. Through this, the embodiment can maximize the heat dissipation effect through the metal layer 221BP and the molding member 430.

In addition, the molding member 430 can have a low permittivity to enhance the heat dissipation characteristics. For example, the permittivity (Dk) of the molding member 430 can be 0.2 to 10. For example, the permittivity (Dk) of the molding member 430 can be 0.5 to 8. For example, the permittivity (Dk) of the molding member 430 can be 0.8 to 5. Accordingly, in the embodiment, the molding member 430 has a low permittivity to enhance the heat dissipation characteristics of the connection member.

The embodiment may include a first insulating layer and a second insulating layer disposed on the first insulating layer and including a cavity. A metal layer is disposed along a circumferential direction of a lower end of a side wall of the cavity and is provided between the first insulating layer and the second insulating layer. The metal layer includes a plurality of metal patterns spaced apart from each other along the circumferential direction.

The plurality of metal patterns may function as a reinforcing member that improves a rigidity of the circuit board. For example, the plurality of metal patterns may disperse or alleviate stress acting on the circuit board, thereby improving warpage characteristics of the circuit board. In addition, the plurality of metal patterns may alleviate horizontal direction expansion of the circuit board due to thermal stress occurring in a manufacturing environment or a usage environment of the circuit board, thereby improving mechanical reliability and/or physical reliability of the circuit board and a semiconductor package including the circuit board.

In addition, the embodiment further includes a connection pattern disposed on the first insulating layer and directly connecting the first pad and the second pad. The connection pattern may be provided to cross between the plurality of metal patterns. At this time, a plurality of connection patterns may be provided. At this time, the plurality of metal patterns are provided spaced apart from each other along the circumferential direction, and accordingly, the plurality of connection patterns may not be electrically connected to each other on the first insulating layer. Therefore, the embodiment can directly connect the first pad and the second pad using the connection pattern, and accordingly, a first through electrode overlapping the first pad in the vertical direction can be omitted. Furthermore, the embodiment can reduce a length of a signal line therebetween by directly connecting the first pad and the second pad using the connection pattern. For example, a signal line including the connection pattern can be shorter than a signal line including the first through electrode. Therefore, the embodiment can minimize signal transmission loss by reducing the signal transmission line between the first pad and the second pad, and thereby improve electrical characteristics. Furthermore, the embodiment can improve the circuit integration by arranging the connection pattern that directly connects the first pad and the second pad.

Meanwhile, the second insulating layer of the embodiment may include a first recess portion provided between the plurality of metal patterns and the lower end of the side wall of the cavity. The first recess portion may disperse or alleviate stress acting on the first insulating layer and the second insulating layer, thereby improving the warpage characteristics of the circuit board. For example, the first recess portion may reduce an area of the interface between the first insulating layer and the second insulating layer, thereby dispersing stress acting on the second insulating layer. Accordingly, the first recess portion may alleviate a phenomenon in which the circuit board is bent in a specific direction (for example, a phenomenon in which both ends of the circuit board are bent upward or a phenomenon in which both ends of the circuit board are bent downward).

In addition, the first insulating layer of the embodiment may include a second recess portion provided along the circumferential direction. The second recess portion may be provided concavely in a vertical direction from the upper surface to the lower surface of the first insulating layer. At this time, the first recess portion is a recess provided in the second insulating layer along the horizontal direction, and the second recess portion is a recess provided in the first insulating layer along the vertical direction. Therefore, the embodiment can disperse or alleviate stress applied to the circuit board by using the first and second recess portions, thereby improving warpage characteristics of the circuit board.

For example, the first and second recess portions can alleviate expansion of the circuit board in the horizontal direction due to thermal stress occurring in the manufacturing environment or the usage environment of the circuit board, thereby improving the mechanical reliability and/or physical reliability of the circuit board and the semiconductor package including the circuit board. At this time, the second insulating layer can include an insulating material different from that of the first insulating layer. Accordingly, the first insulating layer and the second insulating layer can have different coefficients of thermal expansion, and thus warpage of the circuit board in the vertical direction can occur. Accordingly, the first and second recess portions can prevent the circuit board from being bent in a specific direction (for example, the phenomenon in which both ends of the circuit board are bent upward or the phenomenon in which both ends of the circuit board are bent downward).

Therefore, the embodiment can minimize the degree of warpage along the vertical direction of the circuit board and the semiconductor package or the degree of expansion or contraction along the horizontal direction, thereby improving the mechanical and/or physical reliability of the circuit board and the semiconductor package. Furthermore, the embodiment can enable the semiconductor device disposed on the circuit board to operate stably, thereby improving operating characteristics of the electronic product and/or server to which the semiconductor package is applied.

Meanwhile, the plurality of metal patterns of the embodiment can have different widths in the horizontal direction along the circumferential direction. For example, a width of the metal pattern in the horizontal direction in a region with a relatively low metal density can be larger than a width of the metal pattern in the horizontal direction in a region with a relatively high metal density. Accordingly, the embodiment can minimize the warpage of the circuit board caused by a difference in the metal density, thereby further improving the physical reliability and/or electrical reliability of the circuit board and the semiconductor package.

In addition, the embodiment can perform a de-smear process of the second insulating layer after the cavity is formed in a state in which a barrier layer is provided, and based on this, can prevent the glass fiber of the first insulating layer from being exposed, and further solve the physical reliability and/or electrical reliability problem caused thereby. Furthermore, the embodiment can determine the de-smear process conditions under conditions that do not consider the exposure of the glass fiber. For example, the embodiment can determine the de-smear conditions under conditions that can optimally improve the adhesion between the second insulating layer and the second circuit pattern layer, thereby improving the adhesion between the second insulating layer and the second circuit pattern layer without causing the problem of the reinforcing member being exposed.

Meanwhile, the de-smear process of the embodiment can be performed under a state in which a through hole and a cavity penetrating the second insulating layer are formed. Therefore, in the de-smear process, an inner wall of the through hole and an inner wall of the cavity can be surface-treated together. Through this, the adhesion between the second through electrode disposed in the through hole and the second insulating layer can be improved. Furthermore, the embodiment can improve the adhesion between the molding member disposed in the cavity and the second insulating layer.

Furthermore, the molding member can be provided to fill at least one of the first recess portion and the second recess portion. Therefore, the embodiment can further improve the bonding strength between the molding member and the circuit board.

Hereinafter, a method for manufacturing a circuit board according to an embodiment will be described.

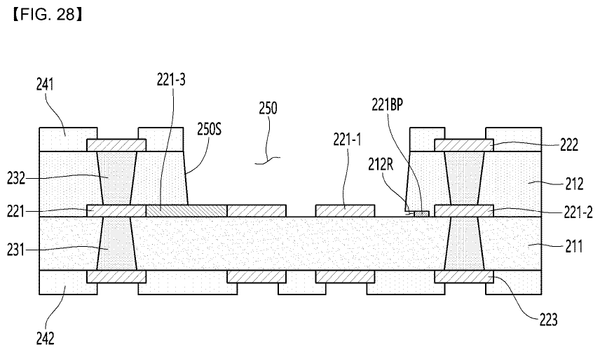

FIGS. 15 to 28 are drawings showing a method for manufacturing a circuit board according to an embodiment in the order of processes.

Referring to FIG. 15, the embodiment prepares an insulating material that serves as a basis for manufacturing a circuit board. For example, the embodiment may prepare an insulating member including a first insulating layer 211 and a metal member (not shown) on the first insulating layer 211.

Referring to FIG. 16, the embodiment may perform a process of forming a first through hole TH1 penetrating the first insulating layer 211.

Referring to FIG. 17, the embodiment may perform a process of forming a circuit pattern layer and a first layer 221a and 223a of a through electrode along the upper surface, lower surface, and inner wall of the first through hole TH1 of the first insulating layer 211. The first layer 221a and 223a can function as a seed layer and can be formed through a chemical plating process.

Referring to FIG. 18, the embodiment may perform a process of forming an electrolytic plating layer by performing electrolytic plating on the first layer 221a and 223a as a seed layer. The electrolytic plating layer can include a second layer 221b of the first circuit pattern layer 221, a second metal layer 223b of the third circuit pattern layer 223, and a first through electrode 231. In addition, the first circuit pattern layer 221 can include a first pad 221-1, a second pad 221-2, and a connection pattern 221-3.

Referring to FIG. 19, the embodiment can perform a process of removing a portion of the first layer 221a and 223a. For example, the embodiment can remove the remaining portion by etching, except for a portion that vertically overlaps the cavity 250 and functions as a barrier layer among the entire region of the first layer 221a and 223a.

That is, in a general circuit board manufacturing process, an entire region of the first layer 221a of the first circuit pattern layer 221 that does not vertically overlap the second layer 221b can be removed. However, the embodiment cannot remove a portion of the first layer 221a that does not vertically overlap the second layer 221b (for example, a region where a cavity is to be formed).

For example, as illustrated in FIG. 20, a portion of the first layer 221a of the first circuit pattern layer 221 can function as a barrier layer 221BR. An outer surface of the barrier layer 221BR may be provided with a plurality of concave portions 221BC spaced apart from each other.

Referring to FIG. 21, the embodiment may perform a process of laminating a second insulating layer 212 on a first insulating layer 211.

Referring to FIG. 22 and FIG. 23, the embodiment may perform a process of forming a cavity 250 and a second through hole TH2 by processing the second insulating layer 212. The second insulating layer 212 may include a photocurable resin, and thus, the cavity 250 and the second through hole TH2 may be formed through a photolithography process including an exposure and development process. The barrier layer 221BR may include an overlapping portion 221BR1 that vertically overlaps the cavity 250 and a non-overlapping portion 221BR2 that does not vertically overlap the cavity 250 and is covered with a second insulating layer 212.

Referring to FIG. 24, the embodiment may perform a de-smear process after the cavity 250 and the second through hole TH2 are formed. Through this, the inner wall of the cavity 250, the inner wall of the second through hole TH2, and the upper surface of the second insulating layer 212 may be de-smear-treated, thereby having a certain level of surface roughness.

At this time, in the case of the embodiment of FIG. 10, at least a part of the upper surface of the first insulating layer 211 vertically overlapping with the cavity 350 (a region vertically overlapping with the concave portion) is not covered with the barrier layer 221BR, and thus a corresponding portion can also be de-smear-processed. Accordingly, a second recess portion 311R can be additionally provided.

Next, referring to FIGS. 25 and 26, the embodiment can remove a portion of the barrier layer 221BR that does not vertically overlap with the first pad 121-1 and the connection pattern 121-3.

At this time, the overlapping portion 221BR1 of the barrier layer 221BR can be completely removed. However, the non-overlapping portion 221BR2 of the barrier layer 221BR can be partially removed. For example, a portion of the non-overlapping portion 221BR2 of the barrier layer 221BR adjacent to the overlapping portion 221BR1 may be removed through overetching. Accordingly, a first recess portion 212R may be formed in the second insulating layer 212, which is a region removed by overetching of the non-overlapping portion 221BR1.

In addition, a portion of the non-overlapping portion 221BR2 of the barrier layer 221BR may not be removed. Accordingly, a metal layer 221BP corresponding to the non-overlapping portion that was not removed may be formed along the first recess portion 212R between the first insulating layer 211 and the second insulating layer 212.

Next, referring to FIG. 27, the embodiment may perform a process of forming a second through electrode 232 and a second circuit pattern layer 222.

In addition, referring to FIG. 28, the embodiment may perform a process of forming a first protective layer 241 on a second insulating layer 212 and a process of forming a second protective layer 242 under the first insulating layer 211.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a first insulating layer;
a second insulating layer disposed on the first insulating layer and including a cavity; and
a circuit pattern layer disposed between the first insulating layer and the second insulating layer,
wherein the circuit pattern layer includes:
a first pad that overlaps the cavity along a vertical direction,
a second pad that overlaps the first pad along a horizontal direction and does not overlap the cavity along the vertical direction, and
a connection pattern that connects between the first pad and the second pad.

2. The circuit board of claim 1, further comprising:
a metal layer disposed between the first insulating layer and the second insulating layer,
wherein the metal layer includes a plurality of metal patterns provided along a circumferential direction of a lower end of a side wall of the cavity and spaced apart from each other.

3. The circuit board of claim 1, wherein the connection pattern includes a first portion that is vertically overlapped with the cavity and is not covered by the second insulating layer, and
a second portion that is not vertically overlapped with the cavity and is covered by the second insulating layer.

4. The circuit board of claim 2, wherein the connection pattern is provided to cross between the plurality of metal patterns on the first insulating layer.

5. The circuit board of claim 4, wherein the connection pattern is not connected to each of the plurality of metal patterns.

6. The circuit board of claim 4, wherein the connection pattern is provided with a plurality of connection patterns, and
wherein at least one of the plurality of connection patterns is connected to at least one of the plurality of metal patterns.

7. The circuit board of claim 2, wherein the plurality of metal patterns have different widths in the horizontal direction along the circumferential direction.

8. The circuit board of claim 2, wherein the plurality of metal patterns are spaced apart with a spacing in a range of 2 μm to 12 μm along the circumferential direction.

9. The circuit board of claim 2, wherein each of the first pad and the second pad includes:
a first layer disposed on the first insulating layer; and a second layer disposed on the first layer, and
wherein a thickness of each of the plurality of metal patterns corresponds to a thickness of the second layer of the first and second pads.

10. The circuit board of claim 2, wherein the second insulating layer includes a first recess portion concavely provided in a horizontal direction from a lower end of a side wall of the cavity toward an outer surface of the second insulating layer.

11. The circuit board of claim 10, wherein the first recess portion includes a plurality of first recesses provided between the plurality of metal patterns and the side wall of the cavity, and
wherein a portion of the side surface of each of the plurality of metal patterns is disposed in the first recess and the cavity.

12. The circuit board of claim 11, wherein a vertical distance of each of the plurality of first recesses in the vertical direction corresponds to a thickness of each of the plurality of metal patterns.

13. The circuit board of claim 11, wherein the first insulating layer includes a second recess portion connected to a lower end of the side wall of the cavity and concavely provided in a vertical direction from an upper surface of the first insulating layer toward a lower surface of the first insulating layer.

14. The circuit board of claim 13, wherein the second recess portion includes a plurality of second recesses spaced apart from each other along the circumferential direction, and
wherein the plurality of first recesses and the plurality of second recesses are alternately disposed along the circumferential direction.

15. A semiconductor package comprising:
a first insulating layer;
a second insulating layer disposed on the first insulating layer and including a cavity;
a first circuit pattern layer including a first pad disposed between the first insulating layer and the second insulating layer and overlapping the cavity in a vertical direction, a second pad not overlapping the cavity in the vertical direction, and a connection pattern connecting the first pad and the second pad;
a connection member disposed on the first pad; and
a metal layer disposed on the first insulating layer along a circumferential direction of a lower end of a side wall of the cavity,
wherein the metal layer includes a plurality of metal patterns spaced apart from each other along the circumferential direction.

16. The semiconductor package of claim 15, further comprising:
a molding member disposed in the cavity to mold the connection member,
wherein the molding member is in contact with the plurality of metal patterns.

17. The semiconductor package of claim 15, wherein the second insulating layer includes a first recess portion concavely provided in a horizontal direction from a lower end of a side wall of the cavity toward an outer surface of the second insulating layer,
wherein the first recess portion includes a plurality of first recesses provided between the plurality of metal patterns and the side wall of the cavity, and
wherein the molding member is provided to fill the plurality of first recesses.

18. The semiconductor package of claim 15, wherein the first insulating layer includes a plurality of second recesses concavely provided in a vertical direction from an upper surface of the first insulating layer toward a lower surface of the first insulating layer and alternately provided with the plurality of first recesses along the circumferential direction, and
wherein the molding member is provided to further fill the plurality of second recesses.

19. The semiconductor package of claim 15, wherein the connecting member includes at least one of an interposer, a semiconductor device, an organic bridge, and an inorganic bridge.
